(19) United States
(12) Patent Application Publication
(10) Pub. No.: US 2020/0335615 A1
(43) Pub. Date: Oct. 22, 2020

(54) SEMICONDUCTOR DEVICE, METHOD FOR MANUFACTURING SEMICONDUCTOR DEVICE, AND ELECTRONIC DEVICE

(71) Applicant: FUJITSU LIMITED, Kawasaki-shi (JP)

(72) Inventors: Atsushi Yamada, Hiratsuka (JP); JUNJI KOTANI, Atsugi (JP)

(73) Assignee: FUJITSU LIMITED, Kawasaki-shi (JP)

(21) Appl. No.: 16/816,324

(22) Filed: Mar. 12, 2020

(30) Foreign Application Priority Data
Apr. 22, 2019 (JP) 2019-080975

(51) Int. Cl. H01L 29/778; H01L 29/20; H01L 33/32; H01L 33/06; H01L 33/00

(52) U.S. Cl. CPC H01L 29/7783; H01L 29/2003; H01L 33/007; H01L 33/06; H01L 33/32

(57) ABSTRACT

A semiconductor device includes a substrate that contains a first nitride semiconductor, an uneven layer that is provided on the substrate, contains a second nitride semiconductor, and has unevenness in a surface, a channel layer that is provided on the uneven layer and contains a third nitride semiconductor, a barrier layer that is provided on the channel layer and contains a fourth nitride semiconductor, wherein, in the uneven layer, an area of a portion that falls within a range within a mode value±1 nm of a position of the surface in a height direction falls within a range of 46% to 75% with respect to an area of the entire surface.

### CROSS-REFERENCE TO RELATED APPLICATION

This application is based upon and claims the benefit of priority of the prior Japanese Patent Application No. 2019-80975, filed on Apr. 22, 2019, the entire contents of which are incorporated herein by reference.

### FIELD

The embodiments discussed herein are related to a semiconductor device, a method for manufacturing a semiconductor device, and an electronic device.

### BACKGROUND

As a semiconductor device using a nitride semiconductor, a light emitting diode (LED) using a gallium nitride (GaN)-based semiconductor is known, for example. Regarding such an LED, a technique of growing an n-type contact layer on a substrate having a recessed portion with the depth of 0.1 μm or more, and sequentially growing an active layer having a quantum well structure and a p-type contact layer on the n-type contact layer is known, for example. In addition, a technique of growing a first semiconductor layer on a wafer having an uneven structure having substantially an n-fold symmetrical array, and sequentially growing a light emitting semiconductor layer and a second semiconductor layer on the first semiconductor layer is known.

Furthermore, as a semiconductor device using a nitride semiconductor, a high electron mobility transistor (HEMT) provided with a barrier layer on a channel layer is known. Regarding such a HEMT, a quantum confinement structure-type HEMT is known, which is provided with a channel layer such as GaN on a first barrier layer such as aluminum nitride (AlN) and provided with a second barrier layer such as AlN on the channel layer, for example.

For example, Japanese Laid-open Patent Publication No. 2007-36174, International Publication Pamphlet No. 2014/192821, and US Patent Application Publication No. 2006/0244011 are disclosed as related arts.

### SUMMARY

According to an aspect of the embodiments, A semiconductor device includes a substrate that contains a first nitride semiconductor, an uneven layer that is provided on the substrate, contains a second nitride semiconductor, and has unevenness in a surface, a channel layer that is provided on the uneven layer and contains a third nitride semiconductor, a barrier layer that is provided on the channel layer and contains a fourth nitride semiconductor, wherein, in the uneven layer, an area of a portion that falls within a range within a mode value±1 nm of a position of the surface in a height direction falls within a range of 46% to 75% with respect to an area of the entire surface.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIGS. 1A and 1B are views illustrating an example of a semiconductor device;

FIGS. 2A and 2B are views illustrating an example of a method for forming a semiconductor device;

FIG. 3 is a view illustrating an example of a semiconductor device according to a first embodiment;

FIGS. 4A and 4B are views illustrating an example of a method for forming the semiconductor device according to the first embodiment;

FIG. 5 is a view illustrating an uneven layer of the semiconductor device according to the first embodiment;

FIGS. 6A to 6C are views illustrating adjustment of the uneven layer of the semiconductor device according to the first embodiment;

FIGS. 7A to 7C are image views of atomic force microscope images of a surface of an AlN substrate and a surface of a GaN layer grown on the AlN substrate;

FIG. 8 is a diagram illustrating an energy band structure of an example of the semiconductor device according to the first embodiment;

FIG. 9 is a view (part 1) illustrating an example of a method for forming a semiconductor device according to a second embodiment;

FIG. 10 is a view (part 2) illustrating an example of the method for forming a semiconductor device according to the second embodiment;

FIG. 11 is a view (part 3) illustrating an example of the method for forming a semiconductor device according to the second embodiment;

FIG. 12 is a view (part 4) illustrating an example of the method for forming a semiconductor device according to the second embodiment;

FIG. 13 is a view (part 5) illustrating an example of the method for forming a semiconductor device according to the second embodiment;

FIG. 14 is a view (part 6) illustrating an example of the method for forming a semiconductor device according to the second embodiment;

FIG. 15 is a view (part 1) illustrating an example of a method for forming a semiconductor device according to a third embodiment;

FIG. 16 is a view (part 2) illustrating an example of the method for forming a semiconductor device according to the third embodiment;

FIG. 17 is a view (part 3) illustrating an example of the method for forming a semiconductor device according to the third embodiment;

FIG. 18 is a view (part 4) illustrating an example of the method for forming a semiconductor device according to the third embodiment;

FIG. 19 is a view (part 1) illustrating an example of a method for forming a semiconductor device according to a fourth embodiment;

FIG. 20 is a view (part 2) illustrating an example of the method for forming a semiconductor device according to the fourth embodiment;

FIG. 21 is a view (part 3) illustrating an example of the method for forming a semiconductor device according to the fourth embodiment;

FIG. 22 is a view (part 4) illustrating an example of the method for forming a semiconductor device according to the fourth embodiment;

FIG. 23 is a view (part 5) illustrating an example of the method for forming a semiconductor device according to the fourth embodiment;

FIG. 24 is a view (part 6) illustrating an example of the method for forming a semiconductor device according to the fourth embodiment;

FIG. 25 is a view illustrating an example of a semiconductor device according to a fifth embodiment;

FIG. 26 is a view illustrating an example of a semiconductor package according to a sixth embodiment;

FIG. 27 is a diagram illustrating an example of a power factor correction circuit according to a seventh embodiment;

FIG. 28 is a diagram illustrating an example of a power supply device according to an eighth embodiment; and

FIG. 29 is a diagram illustrating an example of an amplifier according to a ninth embodiment.

### DESCRIPTION OF EMBODIMENTS

In a semiconductor device such as a HEMT adopting a quantum confinement structure of a nitride semiconductor, there are some cases where confinement of electrons is weakened in the quantum confinement structure obtained by providing a barrier layer of the upper layer on a channel layer, when surface flatness of the channel layer provided on an underlying barrier layer becomes low. When the surface flatness of the channel layer becomes low and the confinement of electrons is weakened due to the low flatness, as described above, characteristics of the semiconductor device adopting the quantum confinement structure of a nitride semiconductor may not be able to be sufficiently improved.

In one aspect, an object of the embodiments is to implement a semiconductor device using a nitride semiconductor and having excellent characteristics.

In the one aspect, according to the embodiments, a semiconductor device using a nitride semiconductor and having excellent characteristics can be implemented.

First, an example of a semiconductor device using a nitride semiconductor will be described.

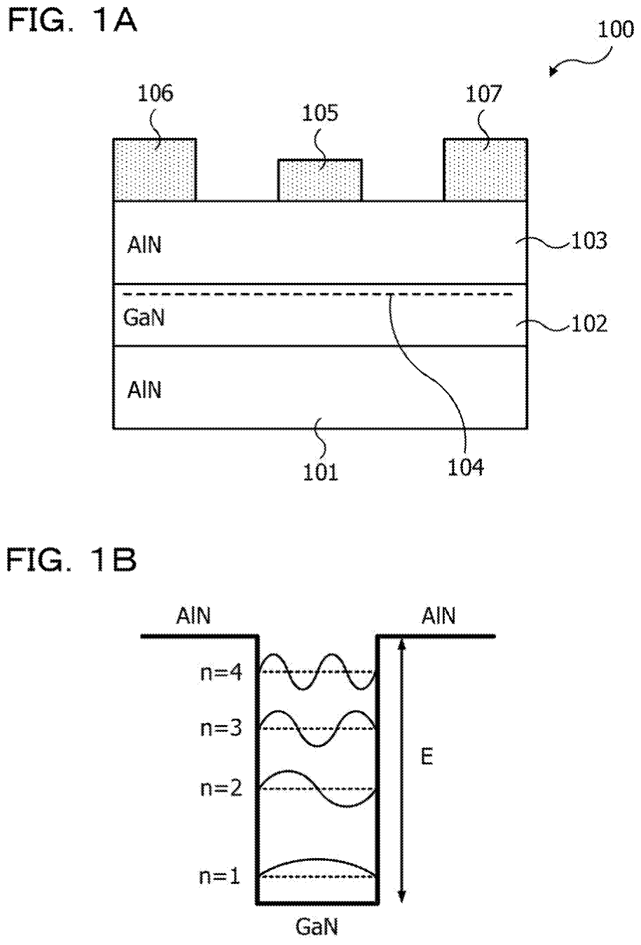

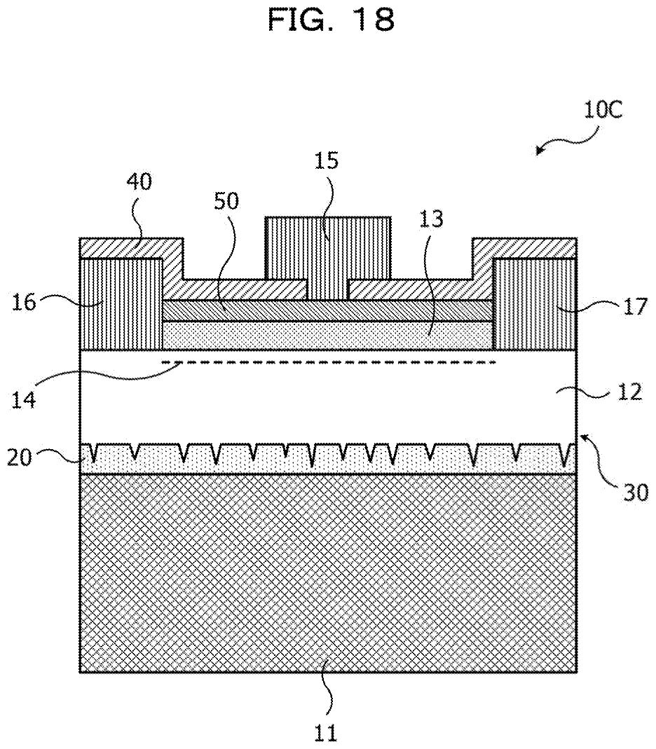

FIGS. 1A and 18 are views illustrating an example of a semiconductor device. FIG. 1A schematically illustrates a cmss-sectional view of a main part of an example of the semiconductor device. FIG. 18 schematically illustrates a view for describing a quantum confinement effect.

A semiconductor device 100 illustrated in FIG. 1A is an example of a HEMT. The semiconductor device 100 includes a substrate 101, a channel layer 102 provided on the substrate 101, and a barrier layer 103 provided on the channel layer 102. A nitride semiconductor is used for the substrate 101, the channel layer 102, and the barrier layer 103. For example, AlN is used for the substrate 101, GaN is used for the channel layer 102, and AlN is used for the barrier layer 103. As the substrate 101, for example, an AlN substrate or a substrate in which a predetermined substrate is provided with an AlN layer functioning as a nucleation layer or a buffer layer is used. In the channel layer 102 near a junction interface with the barrier layer 103, electrons serving as carriers are generated as two dimensional electron gas (2DEG) 104. The semiconductor device 100 further includes a gate electrode 105 provided on the barrier layer 103, and a source electrode 106 and a drain electrode 107 provided on the barrier layer 103 on both sides of the gate electrode 105. A metal is used for the gate electrode 105, the source electrode 106, and the drain electrode 107.

In the semiconductor device 100, a nitride semiconductor having a larger band gap than the nitride semiconductor of the channel layer 102 is used for the substrate 101 and the barrier layer 103. For example, AlN (band gap 6.2 eV) is used for the substrate 101 and the barrier layer 103, and GaN (band gap 3.4 eV) is used for the channel layer 102, as described above. Such a nitride semiconductor is used, and the substrate 101 and the barrier layer 103 are hetero-joined to the channel layer 102. In this case, as illustrated in FIG. 18, a band offset E is generated between a conduction band of the substrate 101 and the barrier layer 103 and a conduction band of the channel layer 102. By the band offset E, a so-called confinement effect (also referred to as an electron confinement effect or a quantum confinement effect) in which electrons as carriers are confined in the channel layer 102 is obtained. When AlN is used for the substrate 101 and the barrier layer 103 and GaN is used for the channel layer 102, a relatively large band offset E is generated. Therefore, a strong confinement effect is obtained and a confinement effect up to a higher-order energy level is obtained.

The stacked structure of the substrate 101, the channel layer 102, and the barrier layer 103 that can obtain an electron confinement effect is also called a quantum confinement structure. The above-described quantum confinement structure using a nitride semiconductor is also referred to as an AlN/GaN/AlN quantum confinement structure or the like. The semiconductor device 100 implements a low leakage current and high carrier mobility by adopting the above-described quantum confinement structure.

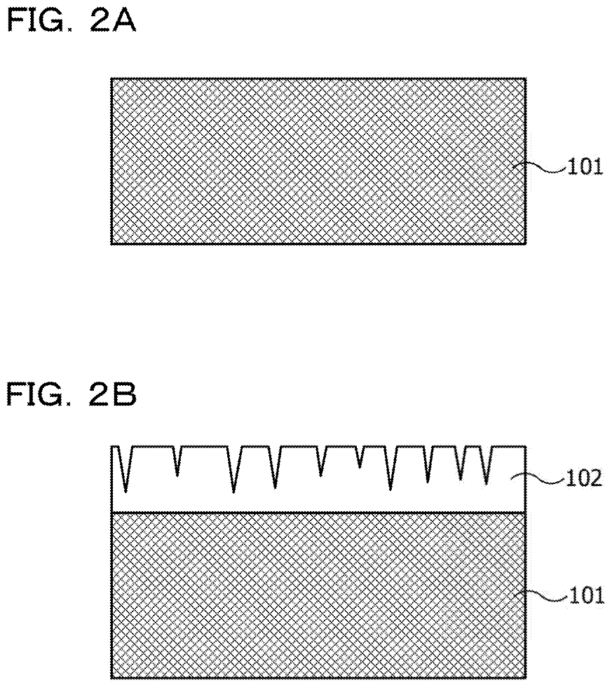

Formation of the semiconductor device 100 adopting the quantum confinement structure includes the following steps as illustrated in FIGS. 2A and 2B.

FIGS. 2A and 2B are views illustrating an example of a method for forming a semiconductor device. Each of FIGS. 2A and 2B schematically illustrates a cross-sectional view of a main part of an example of each step of forming a semiconductor device.

The channel layer 102, for example, GaN is grown on the substrate 101, for example, AlN, as illustrated in FIG. 2A, using a metal organic chemical vapor deposition (MOCVD) method or a metal organic vaper phase epitaxy (MOVPE) method. Then, the barrier layer 103, for example, AlN is grown on the grown channel layer 102 by the MOVPE method.

In this case, there is a relatively large lattice constant difference (about 2.6%) between AlN of the substrate 101 and GaN of the channel layer 102 grown on the substrate 101. When GaN of the channel layer 102 is directly grown on AlN of the substrate 101, a growth mode becomes Volmer-Weber mode due to the relatively large lattice constant difference between AlN of the substrate 101 and GaN of the channel layer 102, and, as illustrated in FIG. 2B, the channel layer 102 having a rough surface and low flatness tends to be grown.

When AlN of the barrier layer 103 is further grown on GaN of the channel layer 102 having low surface flatness to form the quantum confinement structure, a sufficient confinement effect may not be able to be obtained due to a defective heterojunction interface. In this case, the semiconductor device 100 may not be able to function as a high-performance HEMT in which a low leakage current and high carrier mobility are realized by the quantum confinement structure using a nitride semiconductor.

In view of the above points, here, a configuration to be exemplified is adopted as an embodiment, and a semiconductor device using a nitride semiconductor and excellent characteristics is implemented.

### First Embodiment

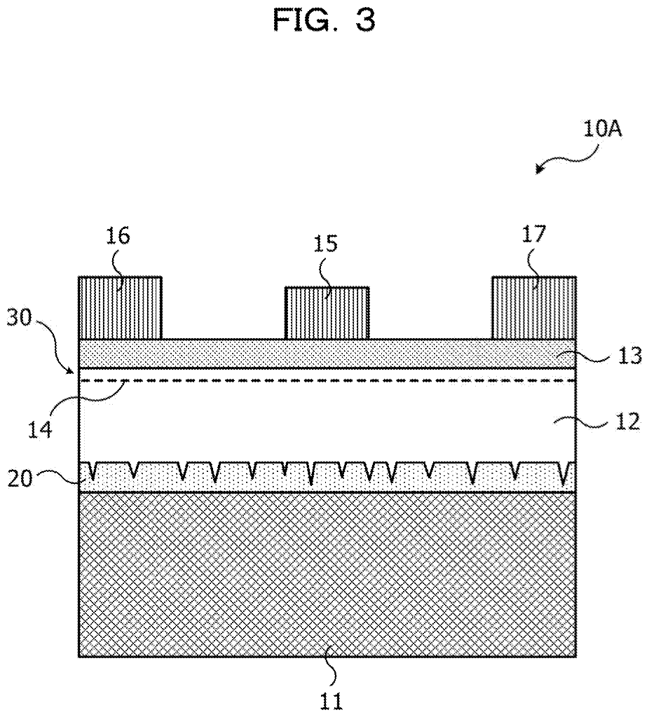

FIG. 3 is a view illustrating an example of a semiconductor device according to a first embodiment. FIG. 3 schematically illustrates a cross-sectional view of a main part of an example of the semiconductor device.

A semiconductor device 10A illustrated in FIG. 3 is an example of a HEMT adopting a quantum confinement structure 30. The semiconductor device 10A includes a substrate 11, an uneven layer 20, a channel layer 12, a barrier layer 13, a gate electrode 15, a source electrode 16, and a drain electrode 17.

A predetermined nitride semiconductor, that is, for example, a nitride semiconductor functioning as a barrier layer on a lower side of the quantum confinement structure 30 or a nitride semiconductor on which the uneven layer 20 functioning as the barrier layer on the lower side of the quantum confinement structure 30 is formable (epitaxially growable), is used for at least a surface of the substrate 11. AlN is used for the nitride semiconductor of the substrate 11, for example. A nitride semiconductor that is a different type from the predetermined nitride semiconductor may be further used for the substrate 11 as long as the predetermined nitride semiconductor is provided for the surface. The substrate 11 is a substrate provided with a nitride semiconductor layer functioning as a nucleation layer or a buffer layer on a nitride semiconductor substrate or a predetermined substrate (not necessarily a nitride semiconductor). The substrate 11 may have a single-layer structure of one type of nitride semiconductor, or a stacked structure of one or more types of nitride semiconductors. An undoped nitride semiconductor is used for the substrate 11, for example.

The uneven layer 20 is provided on the substrate 11. A nitride semiconductor is used for the uneven layer 20. AlN is used for the nitride semiconductor of the uneven layer 20, for example. An undoped nitride semiconductor is used for the uneven layer 20, for example. For example, the uneven layer 20 is formed on the substrate 11, using an MOVPE method. The uneven layer 20 includes a terrace portion, a recessed portion depressed from the terrace portion, and a protruding portion protruding from the terrace portion on the surface (the surface where the channel layer 12 is provided). Details of the uneven layer 20 will be described below.

The channel layer 12 is provided on the uneven layer 20. A nitride semiconductor is used for the channel layer 12. GaN is used for the nitride semiconductor of the channel layer 12, for example. In addition, aluminum gallium nitride (AlGaN) or boron aluminum gallium nitride (BAlGaN) may be used for the nitride semiconductor of the channel layer 12. For example, BₓAl_{y}Ga_{1-x-y}N (0≤x<1, 0≤y<1, and 0≤x+y<1) can be used for the nitride semiconductor of the channel layer 12. The channel layer 12 may have a single-layer structure of one type of nitride semiconductor, or a stacked structure of one or more types of nitride semiconductors. An undoped nitride semiconductor is used for the channel layer 12, for example. For example, the channel layer 12 is formed on the uneven layer 20, using an MOVPE method. The channel layer 12 is also called an electron transit layer.

The barrier layer 13 is provided on the channel layer 12. A nitride semiconductor is used for the barrier layer 13. AlN is used for the nitride semiconductor of the barrier layer 13, for example. In addition, AlGaN may be used for the nitride semiconductor of the barrier layer 13. That is, for example, Al_{z}Ga_{1-z}N (0<z≤1) can be used for the nitride semiconductor of the barrier layer 13. The barrier layer 13 may have a single-layer structure of one type of nitride semiconductor, or a stacked structure of one or more types of nitride semiconductors. An undoped nitride semiconductor is used for the barrier layer 13, for example. For example, the barrier layer 13 is formed on the channel layer 12, using an MOVPE method. The barrier layer 13 is also called an electron supply layer.

Here, nitride semiconductors having different band gaps are used for the channel layer 12 and the barrier layer 13 on the channel layer 12. By providing, on the channel layer 12, the barrier layer 13 using a nitride semiconductor having a larger band gap than the channel layer 12, a heterojunction structure having a band offset is formed. By setting a Fermi level to be higher than (on a higher energy side of) a conduction band at a junction interface between the channel layer 12 and the barrier layer 13, a 2DEG 14 is generated in the channel layer 12 at the junction interface. By providing, on the channel layer 12, the barrier layer 13 using a nitride semiconductor having a larger lattice constant than the channel layer 12, piezoelectric polarization is generated in the barrier layer 13. A high-concentration 2DEG 14 is generated in the channel layer 12 at the junction interface due to spontaneous polarization of the nitride semiconductor used for the barrier layer 13 and piezoelectric polarization generated due to the lattice constant of the nitride semiconductor. A combination of nitride semiconductors to generate the 2DEG 14 near the junction interface between the channel layer 12 and the barrier layer 13 is used for the channel layer 12 and the barrier layer 13.

Moreover, nitride semiconductors having different band gaps are used for the channel layer 12, and the uneven layer 20 or the uneven layer 20 and the substrate 11 below the channel layer 12. By providing, below the channel layer 12, the uneven layer 20 or the uneven layer 20 and the substrate 11 using a nitride semiconductor having a larger band gap than the channel layer 12, a heterojunction structure having a band offset is formed. The quantum confinement structure 30 is formed by the channel layer 12, the uneven layer 20 or the uneven layer 20 and substrate 11 on the lower side of the channel layer 12, and the barrier layer 13 on the upper side of the channel layer 12. In the quantum confinement structure 30, the channel layer 12 functions as a layer in which carrier electrons move, and the uneven layer 20 or the uneven layer 20 and the substrate 11 on the lower layer side and the barrier layer 13 on the upper layer side function as layers for confining carrier electrons in the channel layer 12. The quantum confinement structure 30 realizes a highly efficient and highly reliable HEMT in which diffusion of electrons as carriers to a deep portion is restricted and leakage from the channel layer 12 is suppressed. A combination of nitride semiconductors to form the quantum confinement structure 30 is used for the channel layer 12, and the uneven layer 20 or the uneven layer 20 and the substrate 11 below the channel layer 12.

The gate electrode 15 is provided on the barrier layer 13, for example. The gate electrode 15 functions as a Schottky electrode or a Schottky gate electrode. A metal is used for the gate electrode 15. For example, a metal electrode containing nickel (Ni) and gold (Au) on the nickel is provided as the gate electrode 15. The gate electrode 15 is formed using a vapor deposition method or the like.

Note that an insulating film such as an oxide, a nitride, or an oxynitride may be interposed between the gate electrode 15 and the barrier layer 13. Thereby, a metal insulator semiconductor (MIS) gate structure is implemented. A cap layer using a nitride semiconductor such as GaN or AlGaN may be interposed between the gate electrode 15 and the barrier layer 13.

Furthermore, a cap layer using a nitride semiconductor such as GaN or AlGaN containing p-type impurities or a cap layer using a nitride semiconductor such as indium gallium nitride (InGaN) may be interposed between the gate electrode 15 and the barrier layer 13. Thereby, the 2DEG 14 generated in the channel layer 12 is modulated to decrease the concentration below the gate electrode 15, and a normally-off HEMT is implemented.

The source electrode 16 and the drain electrode 17 are provided on the barrier layer 13 on both sides of the gate electrode 15, for example. The source electrode 16 and the drain electrode 17 are provided on the barrier layer 13 to function as ohmic electrodes. A metal is used for the source electrode 16 and the drain electrode 17. For example, metal electrodes containing tantalum (Ta) and aluminum (Al) on the tantalum are provided as the source electrode 16 and the drain electrode 17. The source electrode 16 and the drain electrode 17 are formed using a vapor deposition method or the like.

Note that the source electrode 16 and the drain electrode 17 may penetrate the barrier layer 13 and be directly connected with the channel layer 12 under the barrier layer 13, instead of being provided on the barrier layer 13. Alternatively, the source electrode 16 and the drain electrode 17 may penetrate the barrier layer 13 and be indirectly connected with the channel layer 12 via a contact layer using a nitride semiconductor such as GaN containing n-type impurities.

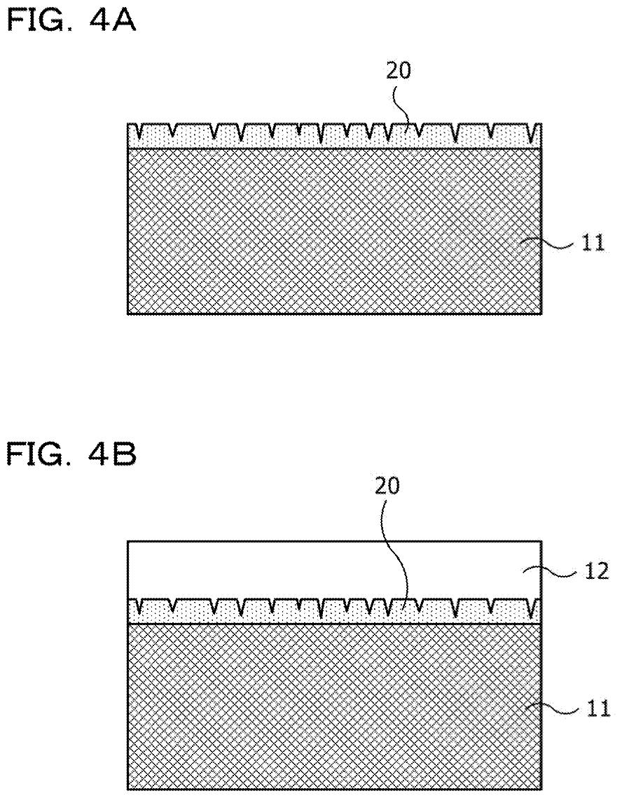

Formation of the semiconductor device 10A provided with the quantum confinement structure 30 as described above includes the following steps as illustrated in FIGS. 4A and 4B.

FIGS. 4A and 4B are views illustrating an example of a method for forming the semiconductor device according to the first embodiment. Each of FIGS. 4A and 4B schematically illustrates a cross-sectional view of a main part of an example of each step of forming a semiconductor device.

First, as illustrated in FIG. 4A, the uneven layer 20 is epitaxially grown on the substrate 11, using an MOVPE method. Then, as illustrated in FIG. 4B, the channel layer 12 is further epitaxially grown on the epitaxially grown uneven layer 20, using an MOVPE method. Note that, hereinafter, epitaxial growth is also simply referred to as growth.

In the formation of the semiconductor device 10A, the uneven layer is first grown on the substrate 11, and the channel layer 12 is grown on the uneven layer 20, whereby the channel layer 12 with suppressed surface roughness and high flatness can be formed. In the formation of the semiconductor device 10A, to form the channel layer 12 with high flatness, an uneven shape of the uneven layer 20 to be grown on the substrate 11 is adjusted in advance before the formation of the channel layer 12.

Here, the uneven layer 20 will be described.

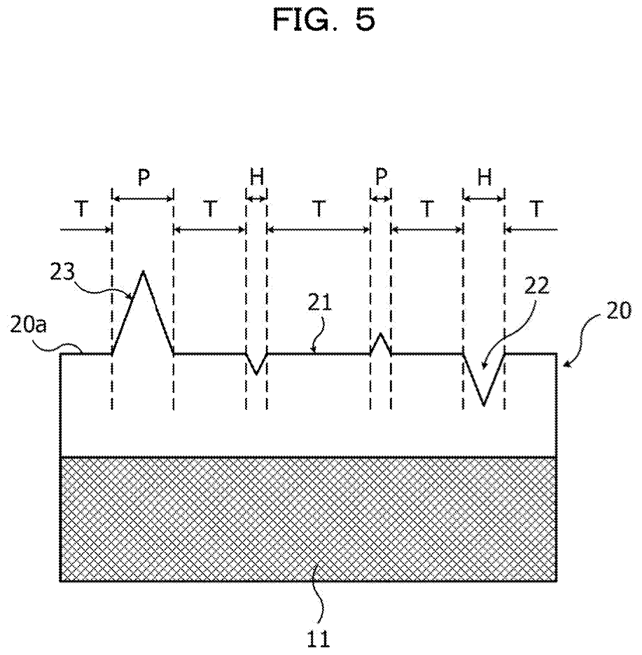

FIG. 5 is a view illustrating the uneven layer of the semiconductor device according to the first embodiment. FIG. 5 schematically illustrates a cross-sectional view of a main part of an example of the substrate and the uneven layer provided on the substrate.

The uneven layer 20 includes a flat terrace portion 21, a recessed portion 22 depressed from the terrace portion 21, and a protruding portion 23 protruding from the terrace portion 21 on a surface 20a (a surface opposite to the substrate 11 side). In FIG. 5, a region of the terrace portion 21 on the surface 20a of the uneven layer 20 is represented by T, a region of the recessed portion 22 is represented by H, and a region of the protruding portion 23 is represented by P, respectively. Note that the surface 20a of the uneven layer 20 may include not only the terrace portion 21, the recessed portion 22, and the protruding portion 23 but also portions having other shapes.

The terrace portion 21 can include a terrace portion 21 having a relatively large area and a terrace portion 21 having a relatively small area. The recessed portion 22 can include a recessed portion 22 that is relatively shallow and a recessed portion 22 that is relatively deep in depth from the terrace portion 21. The protruding portion 23 may include a protruding portion 23 that is relatively low and a protruding portion 23 that is relatively high in height from the terrace portion 21. The uneven shape of the surface 20a of the uneven layer including the terrace portion 21, the recessed portion 22, and the protruding portion 23 is adjusted, and the flatness of the channel layer 12 grown on the uneven layer 20 is improved.

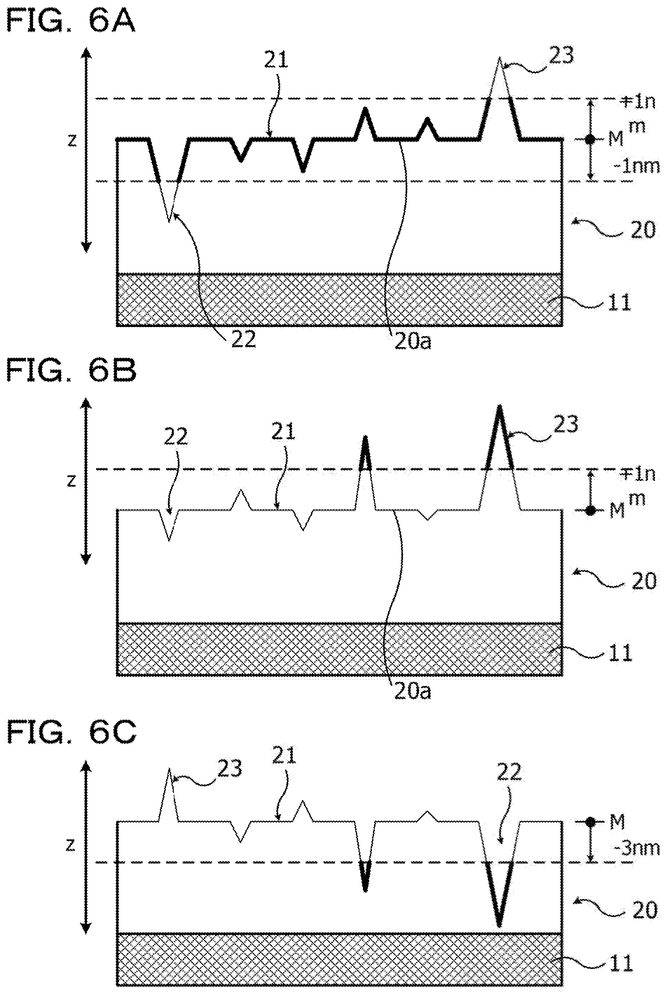

FIGS. 6A to 6C are views illustrating adjustment of the uneven layer of the semiconductor device according to the first embodiment. Each of FIGS. 6A to 6C schematically illustrates a cross-sectional view of a main part of an example of the substrate and the uneven layer provided on the substrate.

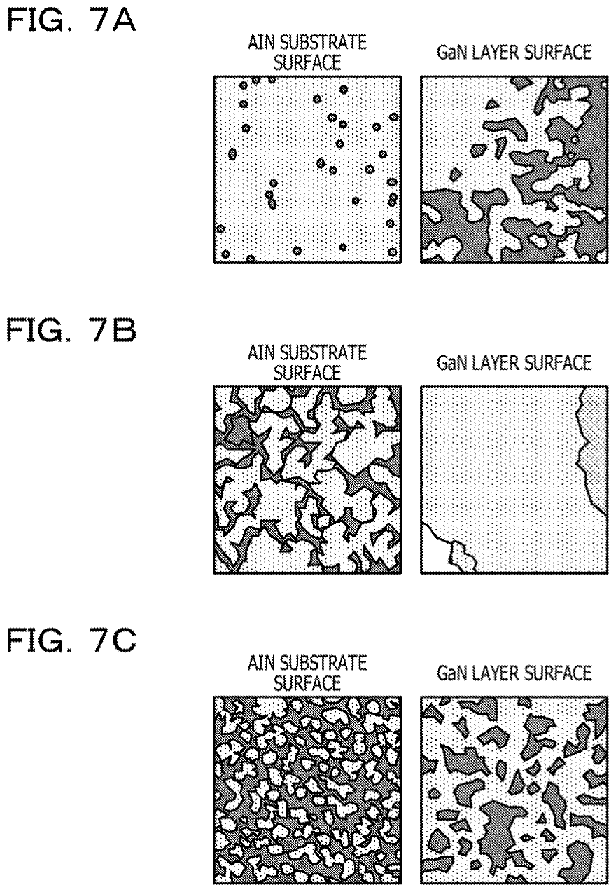

As Illustrated in FIG. 6A, in the uneven layer 20, the uneven shape of the surface 20a is adjusted such that an area S1 of a portion (thick line portion in FIG. 6A) falling within a range within a mode value M±1 nm of a position (surface position) z of the surface 20a in a height direction has a predetermined ratio with respect to an area S of the entire surface 20a. For example, the uneven shape of the surface 20a is adjusted such that a ratio S1/S of the area S1 to the area S falls within a range of 46% to 75% on the basis of findings illustrated in Table 1 and FIGS. 7A to 7C to be described below, and the uneven layer 20 is grown on the substrate 11. The ratio S1/S of the area S1 to the area S may be obtained for the entire uneven layer 20 grown on the substrate 11, or may be obtained for a unit region in the uneven layer 20 grown on the substrate 11, for example, for an arbitrary one portion of a unit region of 1 μm².

When the ratio S1/S of the area S1 to the area S is adjusted to be the predetermined ratio, side surfaces (an inner surface of the recessed portion 22 and an outer surface of a protruding portion 23) of a nitride semiconductor such as AlN used for the uneven layer 20 become present with adequate density on the surface 20a of the uneven layer 20. It is considered that growth nucleus groups of a nitride semiconductor such as GaN used for the channel layer 12 are formed on such side surfaces of the nitride semiconductor in addition to a flat surface (an upper surface of the terrace portion 21) on the surface 20a of the uneven layer 20. Then, it is considered that the nitride semiconductors grown from the large number of growth nucleus groups formed on the flat surface and side surfaces of the nitride semiconductors on the surface 20a of the uneven layer 20 are met, the height imbalance in a growth surface is reduced with the growth, and as a result, the channel layer 12 with high surface flatness can be obtained.

Meanwhile, in a case where the density of the side surfaces of the nitride semiconductor of the uneven layer 20, which is present in the surface 20a of the uneven layer 20, is too small (the area of the flat surface is too large), the density of the growth nucleus groups of the nitride semiconductors of the channel layer 12 becomes small. It is considered that the nitride semiconductors grown up to a certain size from a relatively small number of growth nucleus groups are met and the growth proceeds, and as a result, the channel layer 12 with large surface unevenness and low flatness is obtained. It can also be considered that a similar phenomenon to a case where the nitride semiconductor of the channel layer 12 is directly grown on a flat substrate 11 occurs.

Furthermore, in a case where the density of the side surfaces of the nitride semiconductors of the uneven layer 20, which are present in the surface 20a of the uneven layer 20, is too large (the area of the flat surface is too small), the height imbalance in the growth surface due to the nitride semiconductors grown from the growth nucleus groups of the nitride semiconductors of the channel layer 12 is less easily reduced. As a result, it is considered that the channel layer 12 with large surface unevenness and low flatness is obtained.

In a case where the density of the protruding portions 23 becomes large, the unevenness of the surface of the channel layer 12 obtained by the growth tends to become large. This is because the nitride semiconductor of the channel layer 12 tends to be abnormally grown from the growth nucleus formed on the protruding portion 23, and when the density of the protruding portions 23 becomes large, the unevenness of the surface of the obtained channel layer 12 tends to become large. Therefore, as illustrated in FIG. 68, an area S2 of a portion (thick line portion in FIG. 6) falling within a range of the mode value M+1 nm or more of the position (surface position) z of the surface 20a of the uneven layer 20 in the height direction is favorably adjusted to have a predetermined ratio with respect to the area S of the entire surface 20a. For example, the uneven shape of the surface 20a is adjusted such that a ratio S2/S of the area S2 to the area S becomes less than 3% on the basis of findings illustrated in Table 1 and FIGS. 7A to 7C to be described below, and the uneven layer 20 is grown on the substrate 11. The ratio S2/S of the area S2 to the area S may be obtained for the entire uneven layer 20 grown on the substrate 11, or may be obtained for a unit region In the uneven layer 20 grown on the substrate 11, for example, for an arbitrary one portion of a unit region of 1 μm².

Moreover, in a case where the density of the deep recessed portions 22 becomes large, the unevenness of the surface of the channel layer 12 obtained by the growth tends to become large. This is because the deep recessed portion 22 is not sufficiently buried with the nitride semiconductor of the channel layer 12 to be grown, and the nitride semiconductor of the channel layer 12 grown from the deep recessed portion 22 is more likely to remain depressed after growth than the nitride semiconductor grown from a shallower portion. Therefore, as illustrated in FIG. 6C, an area S3 of a portion (thick line portion In FIG. 6C) falling within a range of the mode value M−3 nm or less of the position (surface position) z of the surface 20a of the uneven layer 20 in the height direction is favorably adjusted to have a predetermined ratio with respect to the area S of the entire surface 20a. For example, the uneven shape of the surface 20a is adjusted such that a ratio S3/S of the area S3 to the area S becomes less than 30% on the basis of findings illustrated in Table 1 and FIGS. 7A to 7C to be described below, and the uneven layer 20 is grown on the substrate 11. The ratio S3/S of the area S3 to the area S may be obtained for the entire uneven layer 20 grown on the substrate 11, or may be obtained for a unit region in the uneven layer 20 grown on the substrate 11, for example, for an arbitrary one portion of a unit region of 1 μm.

The above-described position of the surface 20a of the uneven layer 20 in the height direction, that is, for example, the surface position z can be measured using a scanning probe microscope (SPM) such as a scanning tunneling microscope (STM) or an atomic force microscope (AFM). In addition, the surface position z can be measured using a laser displacement meter.

Table 1 illustrates an example of evaluation results obtained for the adjustment of the uneven shape of the underlying surface of the channel layer 12.

TABLE 1

| | Area | Sample | | | |
|---|---|---|---|---|---|
| Surface position | ratio | A | B | C | D |
| Within mode | S1/S | 98.90% | 75.20% | 48.59% | 46.16% |
| value ± 1 nm | | | | | |
| Mode value + 1 nm | S2/S | 0.01% | 1.90% | 18.92% | 2.57% |
| or more | | | | | |
| Mode value − 3 nm | S3/S | 0.05% | 2.74% | 3.34% | 30.40% |
| or less | | | | | |

| | | | | |
|---|---|---|---|---|
| Flatness determination result | Failure | Pass | Failure | Pass |

Table 1 illustrates an example of results of evaluating (determining pass or failure of) the surface flatness of a GaN layer corresponding to the channel layer 12 in a case where the GaN layer was grown under the same conditions for samples A, B, C, and D having different uneven shapes of a surface of an AlN substrate corresponding to the substrate 11.

From Table 1, the ratio S1/S of the area S1 of the portion falling within the range within the mode value±1 nm of the surface position of the surface of the AlN substrate in the height direction to the area S of the entire surface was 98.90% for the sample A, 75.20% for the sample B, 48.59% for the sample C, and 46.16% for the sample D. The ratio S2/S of the area S2 of the portion falling within the range of the mode value+1 nm or more of the surface position of the surface of the AlN substrate in the height direction to the area S of the entire surface was 0.01% for the sample A, 1.90% for the sample B, 18.92% for the sample C, and 2.57% for the sample D. The ratio S3/S of the area S3 of the portion falling within the range of the mode value−3 nm or less of the surface position of the surface of the AlN substrate in the height direction to the area S of the entire surface was 0.05% for the sample A, 2.74% for the sample B, 3.34% for the sample C, and 30.40% for the sample D.

When the GaN layer was grown on the AlN substrate of the samples A, B, C, and D, and the surface flatness of the GaN layer was evaluated, the sample A failed, the sample B passed, the sample C failed, and the sample D passed.

The sample A is a sample of a substrate in which the ratio S1/S of the area S1 of the portion falling within the range within the mode value±1 nm of the surface position of the surface of the AlN substrate in the height direction to the area S of the entire surface is significantly high, which can be considered to be almost flat. In the sample A having such high flatness, the surface flatness of the GaN layer grown on the substrate is low, and the sample A fails.

The ratio S1/S of the area S1 of the portion falling within the range within the mode value+1 nm of the surface position of the surface of the AlN substrate in the height direction to the area S of the entire surface can be set to fall within the range of 46 (46.16) % to 75 (75.20) % according to the results of the samples B and D that have passed.

Here, the sample C failed even if the ratio S1/S falls within the range of 46% to 75%. This is because the ratio S2/S of the area S2 of the portion falling within the range of the mode value+1 nm or more of the surface position of the surface of the AlN substrate in the height direction to the area S of the entire surface is higher than the other samples B, D, and the like, that is, for example, the surface has many relatively large protruding portions. From the above consideration, the ratio S2/S can be set to be less than 3 (2.57)% according to the results of the samples B and D that have passed. Note that the sample A is considered to fail because the ratio S1/S is high and the flatness is too high although the ratio S2/S is less than 3%.

Furthermore, the ratio S3/S of the area S3 of the portion falling within the range of the mode value−3 nm or less of the surface position of the surface of the AlN substrate in the height direction to the area S of the entire surface can be set to be less than 30 (30.40)% according to the results of the samples B and D that have passed. Note that, although the ratio S3/S is less than 30% in the samples A and C, the sample A is considered to fall because the ratio S1/S is high and the flatness is too high, and the sample C is considered to fail because the ratio S2/S is high and there are too many large protruding portions.

FIGS. 7A to 7C are image views of atomic force microscope images of the surface of the AlN substrate and the surface of the GaN layer grown on the AlN substrate. Note that the AlN substrate corresponds to the above-described substrate 11 or a structure obtained by growing the uneven layer 20 on the substrate 11, and the GaN layer corresponds to the above-described channel layer 12.

FIG. 7A illustrates an image view of the surface of the AlN substrate having high flatness and low density of AlN side surfaces, and an image view of the surface of the GaN layer grown on the AlN substrate. FIG. 7C illustrates an image view of the surface of the AlN substrate having low flatness and high density of AlN side surfaces, and an image view of the surface of the GaN layer grown on the AlN substrate. FIG. 78 illustrates an image view of the surface of the AlN substrate in which the AlN side surfaces are present with adequate density, and an image view of the surface of the GaN layer grown on the AlN substrate. FIGS. 7A to 7C illustrate portions at deep surface positions in the height direction on the surfaces of the AlN substrate and the GaN layer in dark colors.

When the density of the AlN side surfaces is too small or too large, as illustrated in FIGS. 7A and 7C, the surface flatness of the GaN layer grown on the AlN side surfaces becomes low. By use of the AlN substrate with the AlN side surfaces present with adequate density, the GaN layer with high surface flatness can be grown on the AlN substrate, as illustrated in FIG. 78.

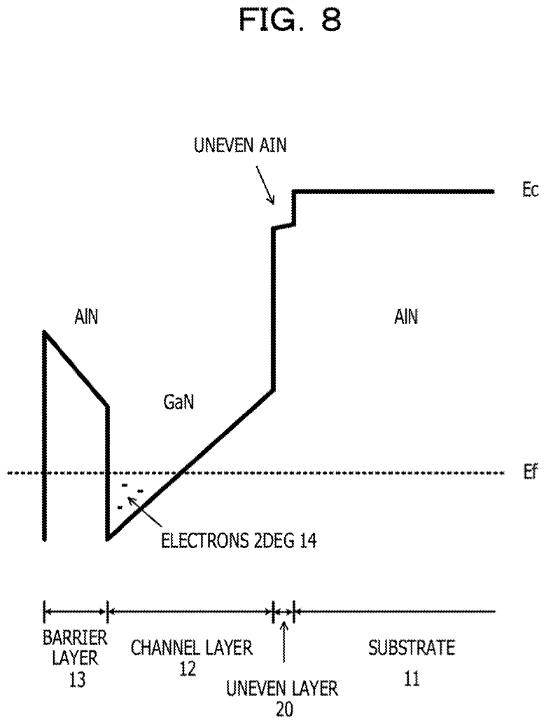

FIG. 8 is a diagram illustrating an energy band structure of an example of the semiconductor device according to the first embodiment. FIG. 8 schematically illustrates an energy band structure in a thickness direction of an example of the semiconductor device.

The energy band structure of the substrate 11, the uneven layer 20, the channel layer 12, and the barrier layer 13 in the semiconductor device 10A having the above-described configuration is as illustrated in FIG. 8. Here, the energy band structure in a case where AlN (band gap 6.2 eV) is used for the substrate 11, the uneven layer 20, and the barrier layer 13, and GaN (band gap 3.4 eV) is used for the channel layer 12 is illustrated as an example. As illustrated in FIG. 8, the above-described quantum confinement structure 30 is implemented, in which electrons as carriers are confined in the channel layer 12 by a band offset generated between a conduction band of the substrate 11, the uneven layer 20, and the barrier layer 13 and a conduction band of the channel layer 12.

The band offset between the uneven layer 20 (uneven AlN) and the channel layer 12 is smaller than a band offset between the substrate 11 (AlN) and the channel layer 12 in a case where the uneven layer 20 is not provided. However, carrier electrons (2DEG 14) gather near the junction interface between the upper barrier layer 13 (AlN) and the channel layer 12 due to an influence of polarization in the channel layer 12 (GaN). Therefore, it can be said that the influence of the band offset reduced by the uneven layer 20 on an electron confinement effect is small.

Note that a similar result is obtained in a case where AlGaN or BAlGaN is used for the channel layer 12, and in a case where AlGaN is used for the barrier layer 13.

As described above, in the semiconductor device 10A, the channel layer 12 is provided on the uneven layer 20 with an adjusted uneven shape, whereby the surface flatness is improved. The barrier layer 13 is provided on the channel layer 12 with such high surface flatness. Thereby, the quantum confinement structure 30 having a high electron confinement effect is implemented. The semiconductor device 10A provided with the quantum confinement structure 30, functioning as a HEMT having high carrier mobility and low leakage current, and having excellent characteristics is implemented.

### Second Embodiment

Here, a first example of a semiconductor device having a configuration as described in the first embodiment and a method for forming the semiconductor device will be described.

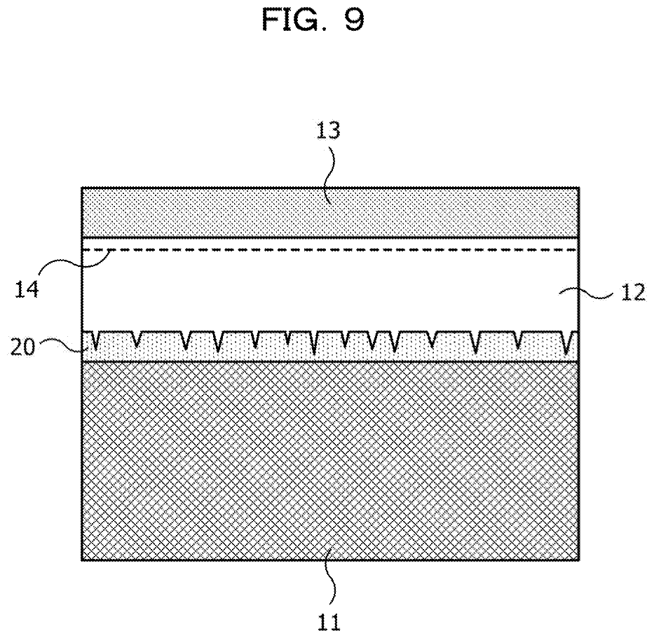

FIGS. 9 to 14 are views illustrating an example of a method for forming a semiconductor device according to a second embodiment. Each of FIGS. 9 to 14 schematically illustrates a cross-sectional view of a main part of an example of each step of forming a semiconductor device.

First, as illustrated in FIG. 9, an uneven layer 20, a channel layer 12, and a barrier layer 13 are sequentially epitaxially grown on a substrate 11, using an MOVPE method. Here, a case in which an AlN free-standing substrate is used as the substrate 11, and the AlN uneven layer 20, the channel layer 12 of BₓAl_{y}Ga_{1-x-y}N (0≤x<1, 0≤y<1, and 0≤x+y<1), and the barrier layer 13 of Al_{z}Ga_{1-z}N (0<z≤1) are grown on a (0001) plane of the AlN substrate will be described as an example. For example, BₓAl_{y}Ga_{1-x-y}N (0≤x<0.2, 0≤y<0.8, and 0≤x+y<1) is grown as the channel layer 12, and Al_{z}Ga_{1-z}N (0.5≤z≤1) is grown as the barrier layer 13. The channel layer 12 favorably has the thickness of 50 nm or less, and more favorably has the thickness of 20 nm or less, in order to cause a quantum confinement effect. The barrier layer 13 is grown with the thickness of 8 nm on such a channel layer 12, for example.

In growing each layer using the MOVPE method, tri-methyl-aluminum (TMAl) is used as an Al source. Tri-methyl-gallium (TMGa) is used as a gallium (Ga) source. Tri-ethyl boron (TEB), a diborane gas, or the like is used as a boron (B) source. A predetermined nitride semiconductor is grown using a mixed gas of one or more of the aforementioned gasses and ammonia (NH₃) and further using hydrogen (H₂) or nitrogen (N₂) as a carrier gas. Supply and stop (switching) of TMAl, TMGa, and TEB, and a flow rate during supply (a mixing ratio with other materials) are appropriately set depending on the nitride semiconductor to be grown. A growth pressure is about 1 kPa to 100 kPa, and a growth temperature is about 700° C. to 1500° C.

Here, in the growth of AlN of the uneven layer 20, a condition is used in which a V/III ratio that is a molar ratio (supply ratio) of the NH₃ gas and the TMAl gas supplied during the growth falls within a range of 22000 to 67000. Note that, to grow a flat layer, the V/III ratio is often set to several tens to several hundreds. In contrast, to the uneven layer 20, the condition of the significantly higher V/II ratio (22000 to 67000) is used.

By use of the condition of such a high V/III ratio, the uneven layer 20 with an adjusted uneven shape as described in the first embodiment is grown. That is, for example, the uneven shape of a surface 20a is adjusted such that a ratio S1/S of an area S1 of a portion falling within a range within a mode value M±1 nm of a surface position z of the surface 20a in a height direction to a surface S of the entire surface 20a falls within a range of 46% to 75%. Furthermore, the uneven shape of the surface 20a is adjusted such that a ratio S2/S of an area S2 of a portion falling within a range of a mode value M+1 nm or more of the surface position z of the surface 20a in the height direction to the surface S of the entire surface 20a becomes less than 3%. Furthermore, the uneven shape of the surface 20a is adjusted such that a ratio S3/S of an area S3 of a portion falling within a range of a mode value M−3 nm or less of the surface position z of the surface 20a in the height direction to the surface S of the entire surface 20a becomes less than 30%. By growing the channel layer 12 on the uneven layer 20 with an adjusted uneven shape of the surface 20a as described above, the channel layer 12 with high surface flatness can be obtained.

When the V/III ratio at the time of growing the uneven layer 20 falls below 22000, the surface 20a with high flat tends to be easily obtained. That is, for example, the possibility that the ratio S1/S exceeds 75% increases. When the V/III ratio at the time of growing the uneven layer 20 exceeds 67,000, a large protruding portion 23 and a deep recessed portion 22 tend to be easily obtained. That is, for example, the possibility that the ratio S2/S exceeds 3% or the possibility that the ratio S3/S exceeds 30% Increases.

After the growth of each layer, a resist having an opening in an element isolation region may be provided using a photolithography technique, and an element isolation region (not illustrated) may be formed by etching (such as dry etching using a chlorine-based gas) or on implantation.

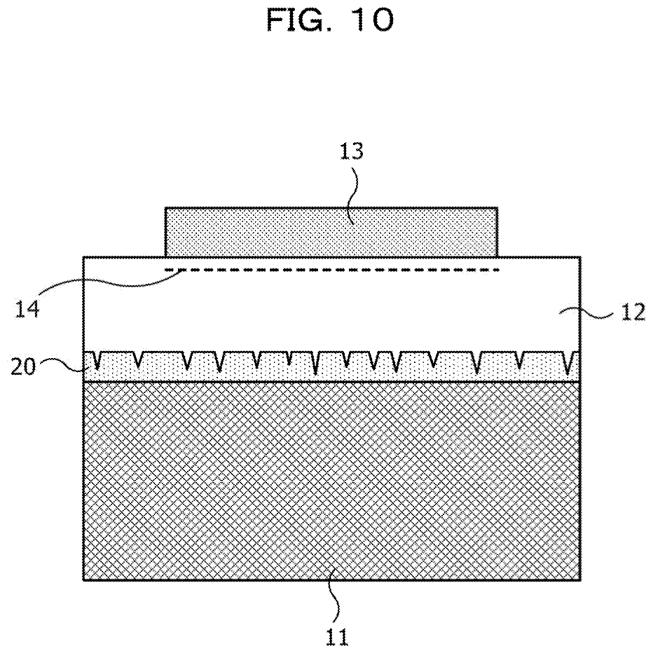

Next, a resist having an opening in a region where a source electrode 16 and a drain electrode 17 are to be formed is provided using a photolithography technique, and etching is performed using a chlorine-based gas. Thereby, a part of the barrier layer 13 is removed, as illustrated in FIG. 10.

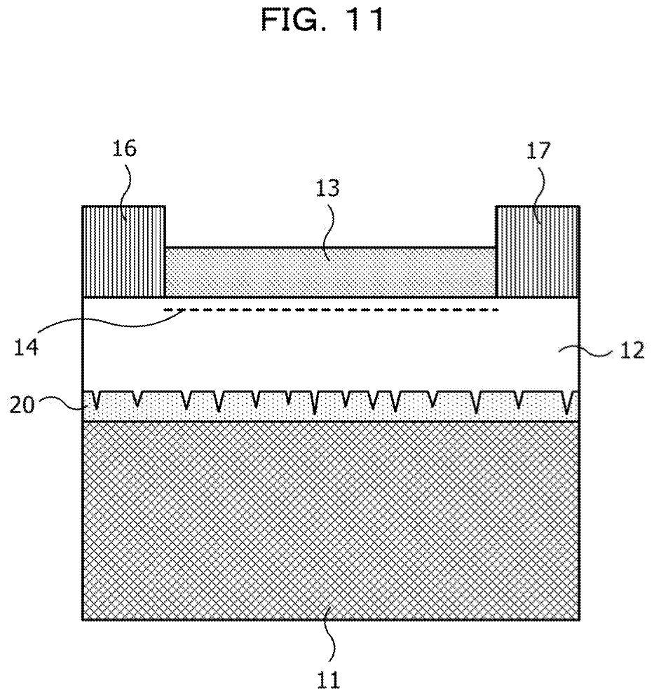

Next, as illustrated in FIG. 11, the source electrode 16 and the drain electrode 17 are formed on the channel layer 12 exposed after the removal of the barrier layer 13. At that time, first, an electrode metal, for example, a stacked body of Ta with the thickness of 20 nm and Al with the thickness of 200 nm is formed on the channel layer 12 exposed from the barrier layer 13, using a photolithography technique, a deposition technique, and a lift-off technique. Thereafter, heat treatment is performed at 400° C. to 1000° C., for example, 550° C. in a nitrogen atmosphere, and the electrode metal is ohmic-connected. Thereby, as illustrated in FIG. 11, the source electrode 16 (ohmic electrode) and the drain electrode 17 (ohmic electrode) are formed.

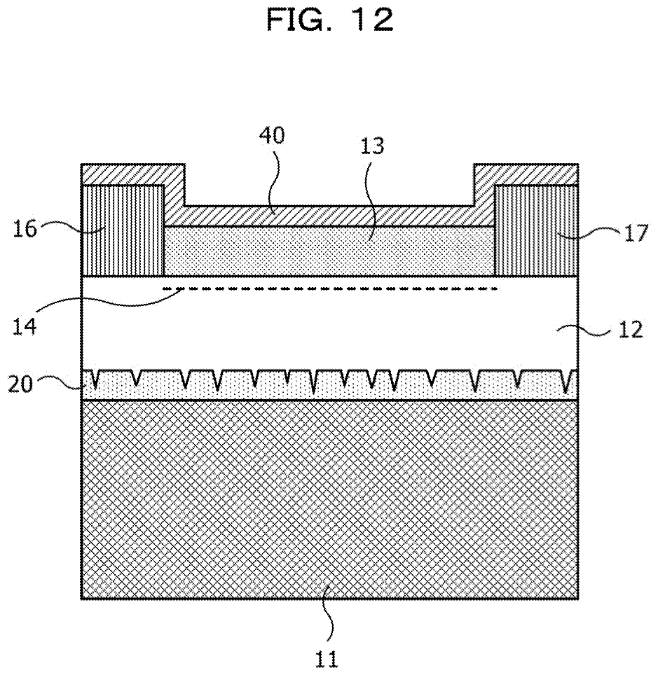

Next, as illustrated in FIG. 12, a passivation film 40 is formed on the barrier layer 13, the source electrode 16, and the drain electrode 17. For example, the passivation film 40 having the thickness of 2 nm to 500 nm, for example, the thickness of 100 nm, is formed using a plasma chemical vapor deposition (CVD) method. The passivation film 40 may be formed using an atomic layer deposition (ALD) method, a sputtering method, or the like. An oxide, nitride, or oxynitride containing silicon (Si), Al, hafnium (Hf), zirconium (Zr), titanium (Ti), Ta, or tungsten (W) is used for the passivation film 40, for example. For example, silicon nitride (SiN) is formed as the passivation film 40.

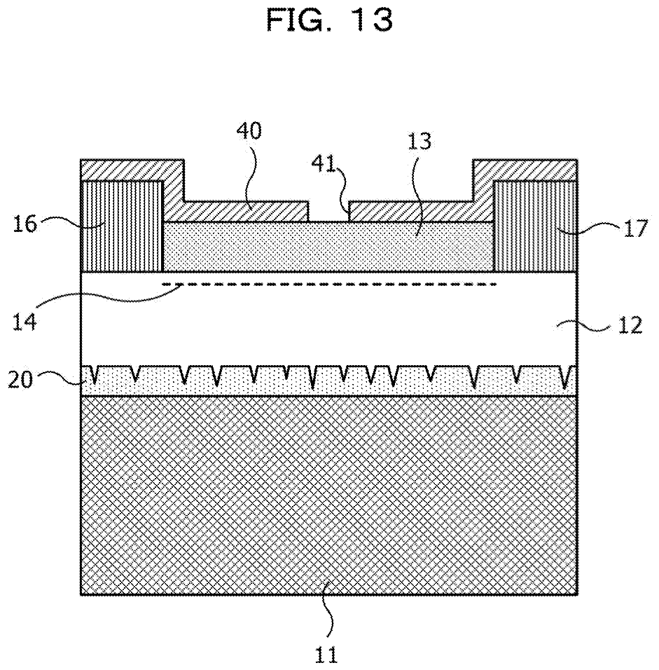

Next, as illustrated in FIG. 13, the passivation film 40 in a region where a gate electrode 15 is to be formed is removed and an opening portion 41 is formed, and a part of the barrier layer 13 is exposed. At that time, first, a resist having an opening in a region where a gate electrode 15 is to be formed is formed using a photolithography technique, and etching is performed using the resist as a mask. By the etching, the passivation film 40 exposed through the opening of the resist is removed. The etching of the passivation film 40 is performed by, for example, dry etching using a fluorine-based or chlorine-based gas. Alternatively, the etching of the passivation film 40 may be performed by wet etching using hydrofluoric acid, buffered hydrofluoric acid, or the like. Thereby, as illustrated in FIG. 13, the passivation film 40 in the region where the gate electrode 15 is to be formed is partially removed, and the opening portion 41 is formed.

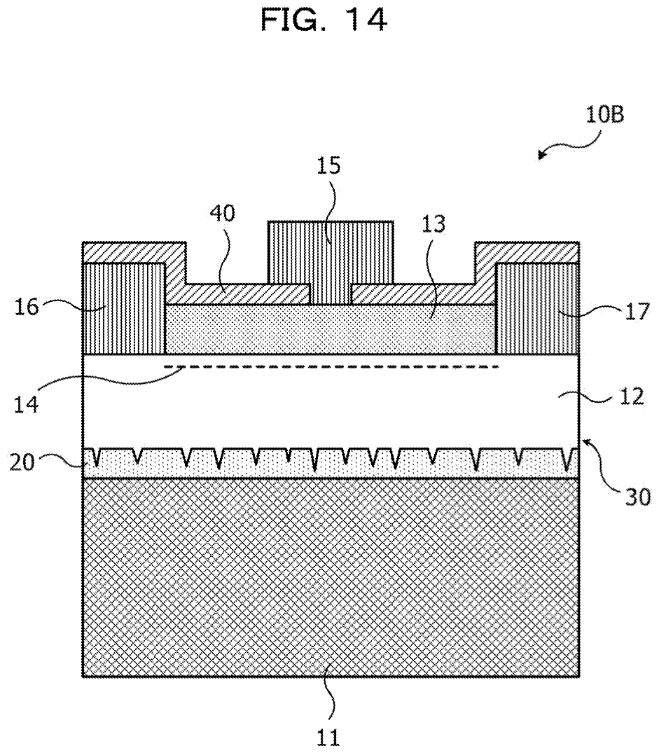

Next, the gate electrode 15 is formed, as illustrated in FIG. 14. For example, an electrode metal, for example, a stacked body of Ni with the thickness of 30 nm and Au with the thickness of 400 nm is formed on the barrier layer 13 exposed from the passivation film 40, using a photolithography technique, a deposition technique, and a lift-off technique. Thereby, the gate electrode 15 (Schottky electrode) is formed, as illustrated in FIG. 14.

A semiconductor device 108 (FIG. 14) having a quantum confinement structure 30 provided with the uneven layer 20 on the substrate 11, and the channel layer 12 and the barrier layer 13 on the uneven layer 20, is obtained by the steps as illustrated in FIGS. 9 to 14.

In the semiconductor device 108, the channel layer 12 is provided on the uneven layer 20 with an adjusted uneven shape, whereby the surface flatness is improved. Thereby, the quantum confinement structure 30 with an enhanced electron confinement effect is implemented. The semiconductor device 101 provided with the quantum confinement structure 30, functioning as a HEMT having high carrier mobility and low leakage current, and having excellent characteristics is implemented.

Note that the types and layer structures of the metals used for the gate electrode 15, the source electrode 16, and the drain electrode 17 of the semiconductor device 108 are not limited to the above examples, and the methods for forming the electrodes are also not limited to the above examples. Each of the gate electrode 15, the source electrode 16, and the drain electrode 17 may have a single-layer structure or a stacked structure. At the time of forming the source electrode 16 and the drain electrode 17, the above-described heat treatment may not be needed as long as ohmic connection is implemented by the formation of the electrode metal. At the time of forming the gate electrode 15, heat treatment may be further performed after the formation of the electrode metal. The structure of the gate electrode 15 is not limited to the above-described Schottky gate structure, and may be a MIS gate structure having an insulating film interposed between the gate electrode 15 and the barrier layer 13.

### Third Embodiment

Here, a second example of a semiconductor device having a configuration as described in the first embodiment and a method for forming the semiconductor device will be described.

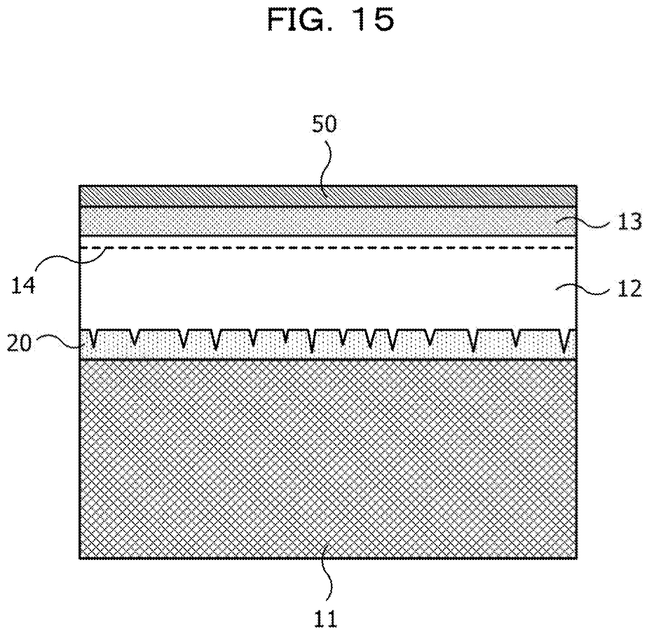

FIGS. 15 to 18 are views illustrating an example of a method for forming a semiconductor device according to a third embodiment. Each of FIGS. to 18 schematically illustrates a cross-sectional view of a main part of an example of each step of forming a semiconductor device.

First, as illustrated in FIG. 15, an uneven layer 20, a channel layer 12, and a barrier layer 13 are sequentially epitaxially grown on a substrate 11, using an MOVPE method, similarly to the above-described second embodiment. For example, an AlN free-standing substrate is used as the substrate 11, and the AlN uneven layer 20, the channel layer 12 of BₓAl_{y}Ga_{1-x-y}N (0≤x<0.2, 0≤y<0.8, and 0≤x+y<1) with the thickness of 50 nm or less, and the barrier layer 13 of Al_{z}Ga_{1-z}N (0.5≤z≤1) with the thickness of 8 nm are grown on a (0001) plane of the AlN substrate. With the provision of the uneven layer 20 on the substrate 11, the channel layer 12 with high surface flatness is grown on the uneven layer 20. The barrier layer 13 is grown on such a channel layer 12. Thereby, the quantum confinement structure 30 having a high electron confinement effect is implemented.

Then, in this example, a cap layer 50, for example, a GaN cap layer 50 with the thickness of 2 nm is further grown on the barrier layer 13, as illustrated in FIG. 15.

After the formation of the cap layer 50, an element isolation region (not illustrated) may be formed.

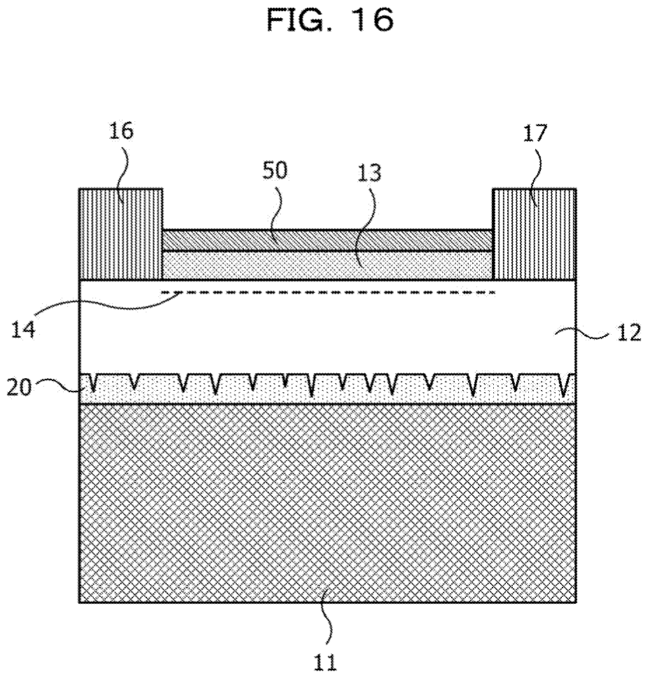

Next, a resist having an opening in a region where a source electrode 16 and a drain electrode 17 are to be formed is provided using a photolithography technique, and etching is performed using a chlorine-based gas. Thereby, each parts of the cap layer 50 and the barrier layer 13 are removed, as illustrated in FIG. 16. Next, an electrode metal, for example, a stacked body of Ta with the thickness of 20 nm and Al with the thickness of 200 nm is formed on the channel layer 12 exposed after removal of the cap layer 50 and the barrier layer 13, using a photolithography technique, a deposition technique, and a lift-off technique. Thereafter, heat treatment is performed at 400° C. to 1000° C., for example, 550° C. in a nitrogen atmosphere, and the electrode metal is ohmic-connected. Thereby, as illustrated in FIG. 16, the source electrode 16 (ohmic electrode) and the drain electrode 17 (ohmic electrode) are formed.

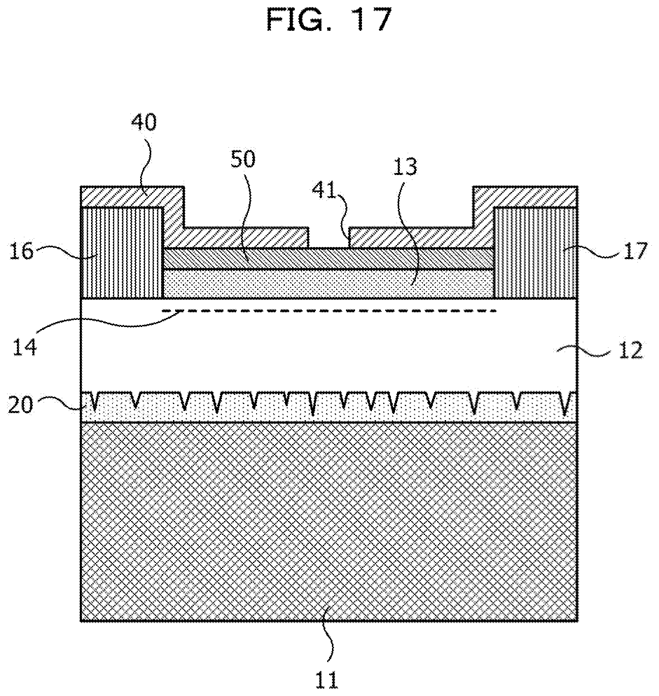

Next, as illustrated in FIG. 17, a passivation film 40 having an opening portion 41 in a region where a gate electrode 15 is to be formed is formed on the cap layer 50, the source electrode 16, and the drain electrode 17. For example, first, the passivation film 40 with the thickness of 2 nm to 500 nm, for example, the thickness of 100 nm, is formed using a plasma CVD method, an ALD method, a sputtering method, or the like. An oxide, nitride, or oxynitride containing Si, Al, Hf, Zr, Ti, Ta, or W is used for the passivation film 40, for example. For example, SiN is formed as the passivation film 40. Next, a resist having an opening in a region where the gate electrode 15 is to be formed is formed using a photolithography technique, and etching is performed using the resist as a mask. By the etching, the passivation film 40 exposed through the opening of the resist is removed. The passivation film 40 is etched by, for example, dry etching using a fluorine-based or chlorine-based gas, or by wet etching using a hydrofluoric acid, a buffered hydrofluoric acid, or the like. Thereby, as illustrated in FIG. 17, the passivation film 40 in the region where the gate electrode 15 is to be formed is partially removed, and the opening portion 41 is formed.

Next, the gate electrode 15 is formed, as illustrated in FIG. 18. For example, an electrode metal, for example, a stacked body of Ni with the thickness of 30 nm and Au with the thickness of 400 nm is formed on the cap layer 50 exposed from the passivation film 40, using a photolithography technique, a deposition technique, and a lift-off technique. Thereby, the gate electrode 15 (Schottky electrode) is formed, as illustrated in FIG. 18.

A semiconductor device 10C (FIG. 18) having the quantum confinement structure 30 provided with the uneven layer 20 on the substrate 11, and the channel layer 12 and the barrier layer 13 on the uneven layer 20, is obtained by the steps as illustrated in FIGS. 15 to 18.

In the semiconductor device 10C, the cap layer 50 is provided between the gate electrode 15 and the barrier layer 13, whereby generation of a gate leak current, diffusion of components of the gate electrode 15 into the barrier layer 13 and the channel layer 12, an increase in ON resistance, and the like are suppressed.

In the semiconductor device 10C, the channel layer 12 is provided on the uneven layer 20 with an adjusted uneven shape, whereby the surface flatness is improved. Thereby, the quantum confinement structure 30 with an enhanced electron confinement effect is implemented. The semiconductor device 10C provided with the quantum confinement structure 30, functioning as a HEMT having high carrier mobility and low leakage current, and having excellent characteristics is implemented.

Note that the types and layer structures of the metals used for the gate electrode 15, the source electrode 16, and the drain electrode 17 of the semiconductor device 10C are not limited to the above examples, and the methods for forming the electrodes are also not limited to the above examples. Each of the gate electrode 15, the source electrode 16, and the drain electrode 17 may have a single-layer structure or a stacked structure. At the time of forming the source electrode 16 and the drain electrode 17, the above-described heat treatment may not be needed as long as ohmic connection is implemented by the formation of the electrode metal. At the time of forming the gate electrode 15, heat treatment may be further performed after the formation of the electrode metal. The structure of the gate electrode 15 is not limited to the above-described Schottky gate structure, and may be a MIS gate structure having an insulating film interposed between the gate electrode 15 and the barrier layer 13.

Furthermore, the cap layer 50 may be selectively provided under the gate electrode 15, and a nitride semiconductor such as GaN or AlGaN containing p-type impurities or a nitride semiconductor such as InGaN may be used for the cap layer 50. By use of such a nitride semiconductor, a 2DEG 14 generated in the channel layer 12 due to fixed charges of the p-type nitride semiconductor and piezoelectric polarization generated in InGaN on the barrier layer 13 is modulated to decrease the concentration below the gate electrode 15. Thereby, the semiconductor device 10C functioning as a normally-off HEMT is implemented.

### Fourth Embodiment

Here, a third example of a semiconductor device having a configuration as described in the first embodiment and a method for forming the semiconductor device will be described.

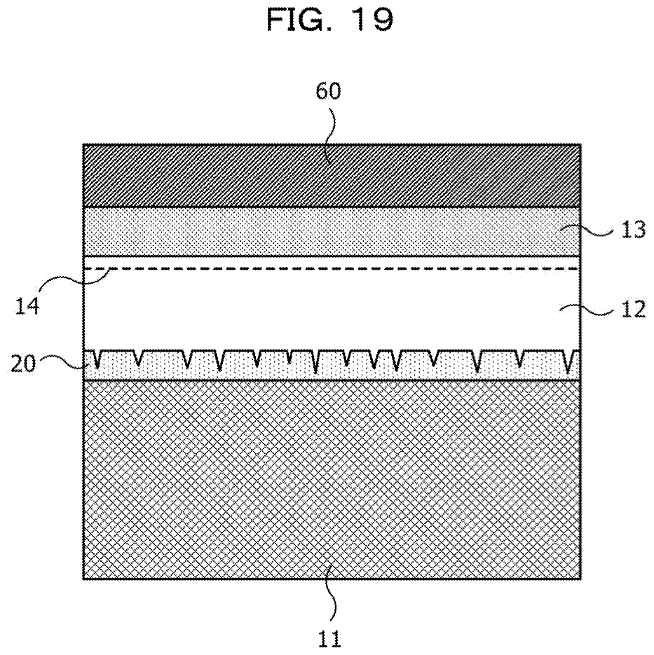

FIGS. 19 to 24 are views illustrating an example of a method for forming a semiconductor device according to a fourth embodiment. Each of FIGS. 19 to 24 schematically illustrates a cross-sectional view of a main part of an example of each step of forming a semiconductor device.

First, as illustrated in FIG. 19, an uneven layer 20, a channel layer 12, and a barrier layer 13 are sequentially epitaxially grown on a substrate 11, using an MOVPE method, similarly to the above-described second embodiment. For example, an AlN free-standing substrate is used as the substrate 11, and the AlN uneven layer 20, the channel layer 12 of BₓAl_{y}Ga_{1-x-y}N (0≤x<0.2, 0≤y<0.8, and 0≤x+y<1) with the thickness of 50 nm or less, and the barrier layer 13 of Al_{z}Ga_{1-z}N (0.5≤z≤1) with the thickness of 8 nm are grown on a (0001) plane of the AIN substrate. With the provision of the uneven layer 20 on the substrate 11, the channel layer 12 with high surface flatness is grown on the uneven layer 20. The barrier layer 13 is grown on such a channel layer 12. Thereby, the quantum confinement structure 30 having a high electron confinement effect is implemented.

Then, in this example, a surface protective film 60 is further formed on the barrier layer 13, using a plasma CVD method, an ALD method, a sputtering method, or the like, as illustrated in FIG. 19. An oxide, nitride, or oxynitride containing Si, Al, Hf, Zr, Ti, Ta, or W is used for the surface protective film 60, for example. For example, silicon oxide (SiO₂) is formed as the surface protective film 60.

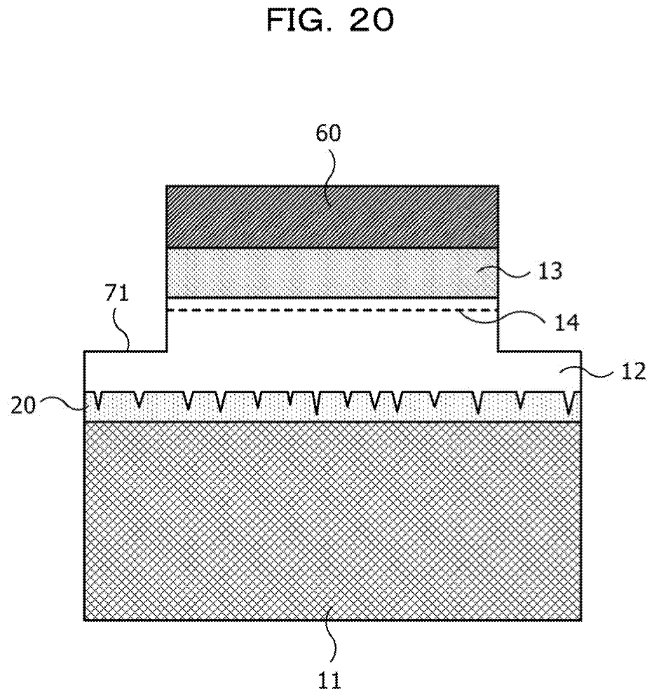

Next, a resist having an opening in a region where a source electrode 16 and a drain electrode 17 are to be formed is provided using a photolithography technique, and each parts of the surface protective film 60, the barrier layer 13, and the channel layer 12 are removed by etching using a chlorine-based gas. Thereby, a state In which a groove 71 is formed as illustrated in FIG. 20 is obtained.

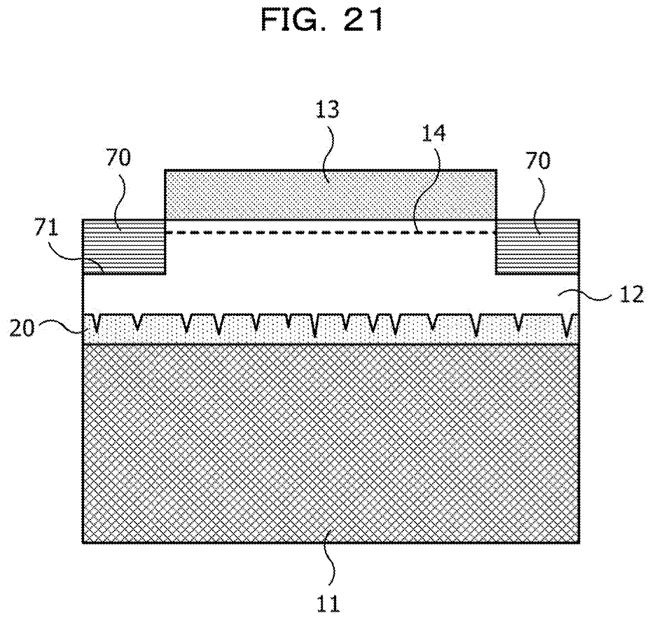

Next, as illustrated in FIG. 21, an n-type contact layer 70 is grown by an MOVPE method on the channel layer 12 exposed to the groove 71 formed by partially removing the surface protective film 60, the barrier layer 13, and the channel layer 12, respectively. GaN containing n-type impurities such as Si (n-type GaN) is used for the n-type contact layer 70. For example, n-type GaN with the thickness of 50 nm and the doping concentration of 1×10¹⁹ cm⁻³ is grown by an MOVPE method in which a silane gas that is a material of the n-type impurity Si is added at a predetermined flow rate to a mixed gas of TMGa that is a material of GaN, and NH₃. As the n-type impurities, germanium (Ge), oxygen (O), or the like may be used in addition to Si. After the formation of the n-type contact layer 70, the surface protective film 60 is removed.

After the formation of the n-type contact layer 70, an element isolation region (not illustrated) may be formed.

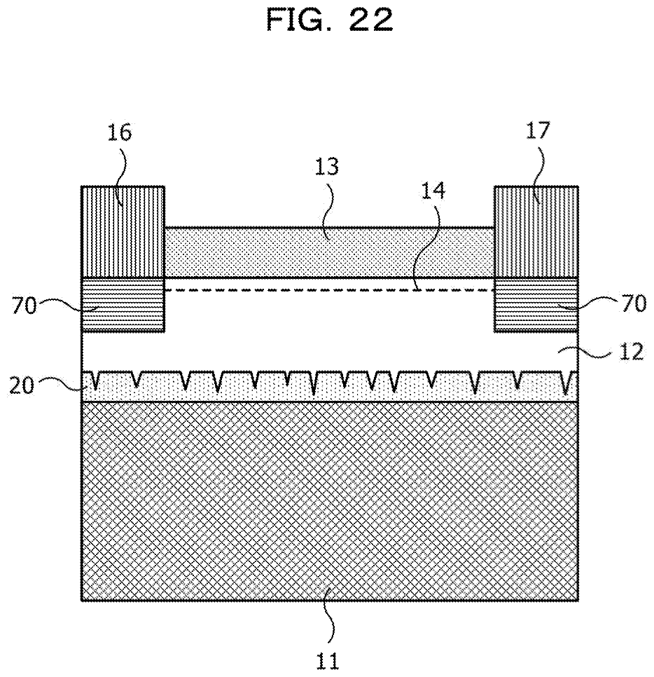

Next, an electrode metal, that is, for example, a stacked body of Ta with the thickness of 20 nm and Al with the thickness of 200 nm is formed on the n-type contact layer 70, for example, on a region where the source electrode 16 and the drain electrode 17 are to be formed, using a photolithography technique, a deposition technique, and a lift-off technique. Thereafter, heat treatment is performed at 400° C. to 1000° C., for example, 550° C. in a nitrogen atmosphere, and the electrode metal is ohmic-connected. Thereby, as illustrated in FIG. 22, the source electrode 16 (ohmic electrode) and the drain electrode 17 (ohmic electrode) are formed.

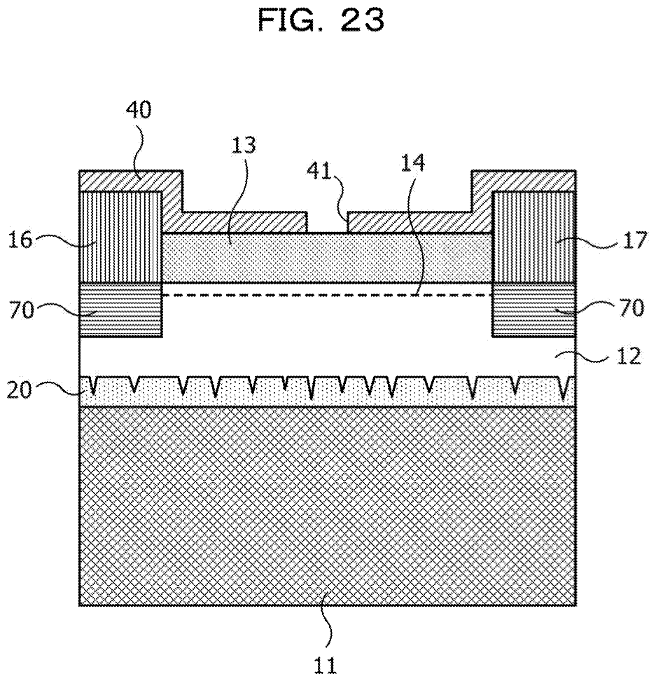

Next, as illustrated in FIG. 23, a passivation film 40 having an opening portion 41 in a region where a gate electrode 15 is to be formed is formed on the barrier layer 13, the source electrode 16, and the drain electrode 17. For example, first, the passivation film 40 with the thickness of 2 nm to 500 nm, for example, the thickness of 100 nm, is formed using a plasma CVD method, an ALD method, a sputtering method, or the like. An oxide, nitride, or oxynitride containing Si, A, Hf, Zr, Ti, Ta, or W is used for the passivation film 40, for example. For example, SiN is formed as the passivation film 40. Next, a resist having an opening in a region where the gate electrode 15 is to be formed is formed using a photolithography technique, and etching is performed using the resist as a mask. By the etching, the passivation film 40 exposed through the opening of the resist is removed. The passivation film 40 is etched by, for example, dry etching using a fluorine-based or chlorine-based gas, or by wet etching using a hydrofluoric acid, a buffered hydrofluoric acid, or the like. Thereby, as illustrated in FIG. 23, the passivation film 40 in the region where the gate electrode 15 is to be formed is partially removed, and the opening portion 41 is formed.

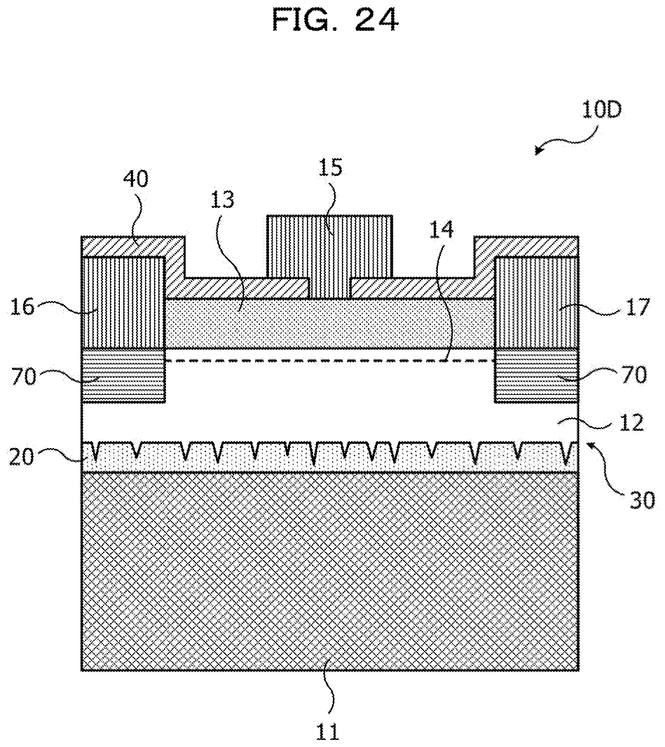

Next, the gate electrode 15 is formed, as illustrated In FIG. 24. For example, an electrode metal, for example, a stacked body of Ni with the thickness of 30 nm and Au with the thickness of 400 nm is formed on the barrier layer 13 exposed from the passivation film 40, using a photolithography technique, a deposition technique, and a lift-off technique. Thereby, the gate electrode 15 (Schottky electrode) is formed, as illustrated in FIG. 24.

A semiconductor device 10D (FIG. 18) having a quantum confinement structure 30 provided with the uneven layer 20 on the substrate 11, and the channel layer 12 and the barrier layer 13 on the uneven layer 20, is obtained by the process as illustrated in FIGS. 19 to 24.

The semiconductor device 10D is provided with the source electrode 16 and the drain electrode 17 on the n-type contact layer 70, whereby a contact resistance between the n-type contact layer 70, and the source electrode 16 and the drain electrode 17 is reduced. Thereby, low-resistance ohmic connection is implemented.

In the semiconductor device 10, the channel layer 12 is provided on the uneven layer 20 with an adjusted uneven shape, whereby the surface flatness is improved. Thereby, the quantum confinement structure 30 with an enhanced electron confinement effect is Implemented. The semiconductor device 10D provided with the quantum confinement structure 30, functioning as a HEMT having high carrier mobility and low leakage current, and having excellent characteristics is implemented.

Note that the types and layer structures of the metals used for the gate electrode 15, the source electrode 16, and the drain electrode 17 of the semiconductor device 10D are not limited to the above examples, and the methods for forming the electrodes are also not limited to the above examples. Each of the gate electrode 15, the source electrode 16, and the drain electrode 17 may have a single-layer structure or a stacked structure. At the time of forming the source electrode 16 and the drain electrode 17, the above-described heat treatment may not be needed as long as ohmic connection is implemented by the formation of the electrode metal. At the time of forming the gate electrode 15, heat treatment may be further performed after the formation of the electrode metal. The structure of the gate electrode 15 is not limited to the above-described Schottky gate structure, and may be a MIS gate structure having an insulating film interposed between the gate electrode 15 and the barrier layer 13.

Furthermore, in the semiconductor device 10D, a cap layer 50 using a nitride semiconductor may be provided on the barrier layer 13, according to the example of the semiconductor device 10C as described in the third embodiment.

### Fifth Embodiment

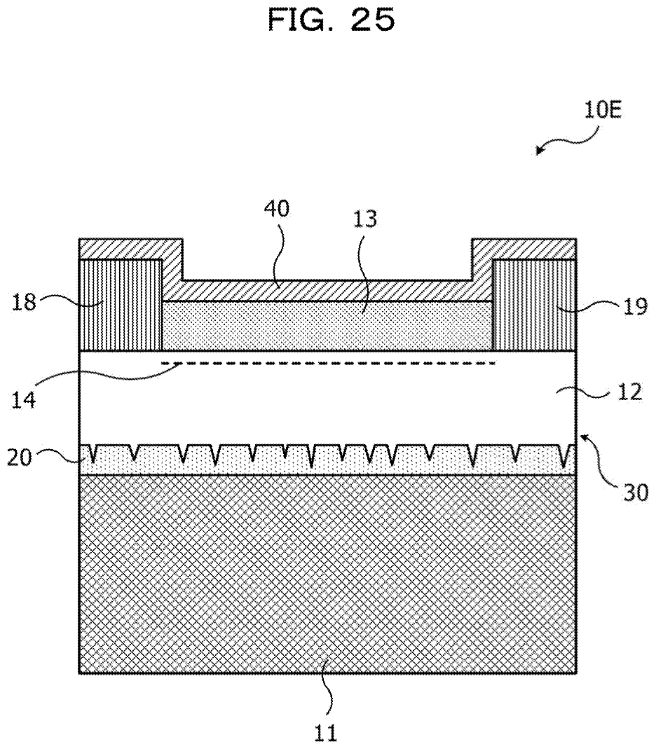

FIG. 25 is a view illustrating an example of a semiconductor device according to a fifth embodiment. FIG. 25 schematically illustrates a cross-sectional view of a main part of an example of the semiconductor device.

A semiconductor device 10E illustrated in FIG. 25 is an example of a Schottky barrier diode (SBD). The semiconductor device 10E includes a substrate 11, an uneven layer 20, a channel layer 12, a barrier layer 13, a cathode electrode 18 (ohmic electrode), and an anode electrode 19 (Schottky electrode).

A nitride semiconductor similar to the nitride semiconductor described for the semiconductor device 10B (FIG. 14) or the like is used for the substrate 11, the uneven layer 20, the channel layer 12, and the barrier layer 13 of the semiconductor device 10E. With the provision of the uneven layer 20 on the substrate 11, the channel layer 12 with high surface flatness is grown on the uneven layer 20. The barrier layer 13 is grown on such a channel layer 12. Thereby, the quantum confinement structure 30 having a high electron confinement effect is Implemented. A metal is used for the cathode electrode 18 and the anode electrode 19 of the semiconductor device 10E. The cathode electrode 18 is provided on the channel layer 12 to function as an ohmic electrode, and the anode electrode 19 is provided on the channel layer 12 to function as a Schottky electrode. A passivation film 40 may be provided on the barrier layer 13, the cathode electrode 18, and the anode electrode 19, as illustrated in FIG. 25.

The semiconductor device 10E having the above configuration can be formed according to the example of the method described with reference to FIGS. 9 to 12 in the second embodiment.

That is, for example, first, according to the example in FIG. 9, the uneven layer 20, the channel layer 12, and the barrier layer 13 are sequentially epitaxially grown on the substrate 11, using an MOVPE method.

Next, according to the example In FIG. 10, the barrier layer 13 in a region where the cathode electrode 18 and the anode electrode 19 are to be formed is partially removed.

Next, according to the example above in FIG. 11, an electrode metal is formed on the channel layer 12, and the cathode electrode 18 and the anode electrode 19 are formed. At that time, the cathode electrode 18 is formed on the channel layer 12 so as to function as an ohmic electrode, and the anode electrode 19 is formed on the channel layer 12 so as to function as a Schottky electrode. In the formation of the semiconductor device 10E, the formation of the cathode electrode 18 and the anode electrode 19 may be performed in separate steps to respectively implement ohmic connection and Schottky connection, or electrode metals of different types from each other may be used.

Next, a passivation film 40 is formed on the barrier layer 13, the cathode electrode 18, and the anode electrode 19 according to the example in FIG. 12 above.

The semiconductor device 10E having the configuration illustrated in FIG. 25 is formed using such a method, for example.

According to the semiconductor device 10E, the quantum confinement structure 30 realizes a highly efficient and highly reliable SBD in which diffusion of electrons as carriers to a deep portion is restricted and leakage from the channel layer 12, that is, for example, generation of a leakage current is suppressed.

Note that the semiconductor device 10E described in the fifth embodiment may be mixedly mounted on one common substrate with the semiconductor device 10A described in the first embodiment or the semiconductor device 10B, 10C, or 10D described in the second, third, or fourth embodiment. For example, a semiconductor device in which the semiconductor device 10B and the semiconductor device 10E are mixedly mounted on one substrate can be obtained.

The semiconductor devices 10A, 10, 10C, 10D, 10E and the like having the configurations described in the first to fifth embodiments can be applied to various electronic devices. As examples, cases in which the semiconductor device having the above configuration is applied to a semiconductor package, a power factor correction circuit, a power supply device, and an amplifier will be described below.

### Sixth Embodiment

Here, an application of a semiconductor device having a configuration as described above to a semiconductor package will be described as a sixth embodiment.

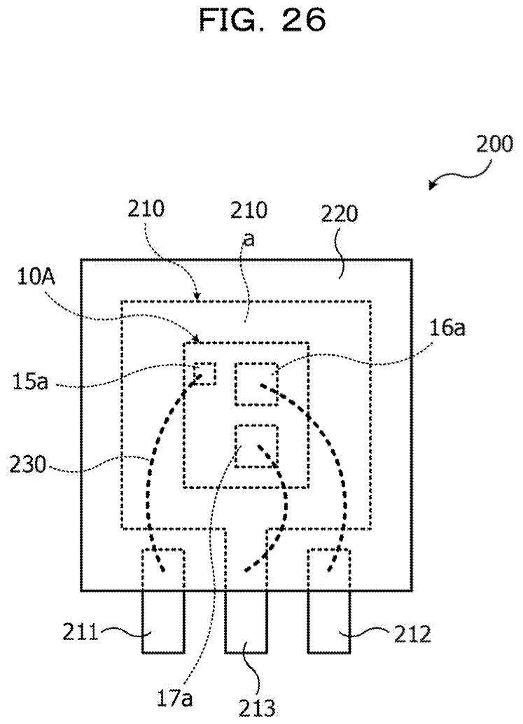

FIG. 26 is a view illustrating an example of a semiconductor package according to the sixth embodiment. FIG. 26 schematically illustrates a plan view of a main part of an example of the semiconductor package.

A semiconductor package 200 illustrated in FIG. 26 is an example of a discrete package. The semiconductor package 200 includes, for example, the semiconductor device 10A described in the first embodiment above, a lead frame 210 on which the semiconductor device 10A is mounted, and a resin 220 that seals the semiconductor device 10A and the lead frame 210.

The semiconductor device 10A is mounted on a die pad 210a of the lead frame 210, using a die attach material or the like (not illustrated). The semiconductor device 10A includes a pad 15a connected to a gate electrode 15 described above, a pad 16a connected to a source electrode 16, and a pad 17a connected to a drain electrode 17. The pad 15a, the pad 16a, and the pad 17a are respectively connected to a gate lead 211, a source lead 212, and a drain lead 213 of the lead frame 210, using a wire 230 of Al or the like. The wire 230 connecting the lead frame 210 and the semiconductor device 10A mounted on the lead frame 210 is sealed by the resin 220 so as to partially expose the gate lead 211, the source lead 212, and the drain lead 213, respectively.

For example, the semiconductor package 200 using the semiconductor device 10A described in the first embodiment above and having such a configuration is obtained. Here, the semiconductor device 10A has been used as an example. However, a high-performance semiconductor package can be similarly obtained using another semiconductor device 10B, 10C, 10D, or the like functioning as an HEMT.

As described above, in the semiconductor devices 10A, 10B, 10C, 10D, and the like, the channel layer 12 is provided on the uneven layer 20 having an adjusted uneven shape, and the surface flatness of the channel layer 12 is improved. Thereby, the quantum confinement structure 30 with an enhanced electron confinement effect is implemented. The high-performance semiconductor package 200 using the semiconductor device 10A, 10B, 10C, 10D, or the like, having such a quantum confinement structure 30, functioning as a HEMT having a high carrier mobility and a low leakage current, and having excellent characteristics is implemented.

Furthermore, a discrete package can be obtained using the semiconductor device 10E or the like functioning as an SBD. As described above, in the semiconductor device 10E and the like, the channel layer 12 is provided on the uneven layer 20 having an adjusted uneven shape, and the surface flatness of the channel layer 12 is improved. Thereby, the quantum confinement structure 30 with an enhanced electron confinement effect is implemented. The high-performance semiconductor package 200 using the semiconductor device 10E or the like, having such a quantum confinement structure 30, functioning as an SBD having a high carrier mobility and a low leakage current, and having excellent characteristics is implemented.

### Seventh Embodiment

Here, an application of a semiconductor device having a configuration as described above to a power factor correction circuit will be described as a seventh embodiment.

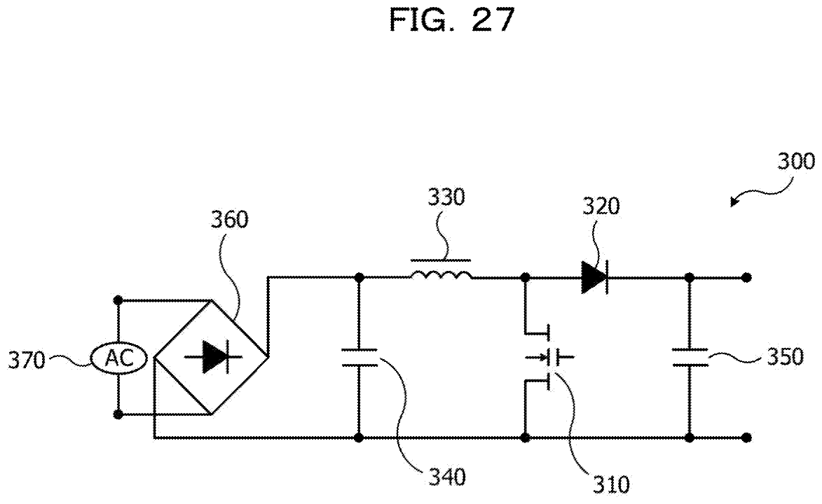

FIG. 27 is a diagram illustrating an example of a power factor correction circuit according to the seventh embodiment. FIG. 27 illustrates an equivalent circuit diagram of an example of a power factor correction circuit.

A power factor correction (PFC) circuit 300 illustrated In FIG. 27 includes a switch element 310, a diode 320, a choke coil 330, a capacitor 340, a capacitor 350, a diode bridge 360, and an AC power supply 370 (AC).

In the PFC circuit 300, a drain electrode of the switch element 310 is connected to an anode terminal of the diode 320 and one terminal of the choke coil 330. A source electrode of the switch element 310 is connected to one terminal of the capacitor 340 and one terminal of the capacitor 350. The other terminal of the capacitor 340 and the other terminal of the choke coil 330 are connected. The other terminal of the capacitor 350 and a cathode terminal of the diode 320 are connected. Furthermore, a gate driver is connected to a gate electrode of the switch element 310. The AC power supply 370 is connected between both terminals of the capacitor 340 via the diode bridge 360, and a DC power supply (DC) is extracted from both terminals of the capacitor 350.

For example, the above-described semiconductor device 10A, 10B, 10C, 10D, or the like which functions as a HEMT is used for the switch element 310 of the PFC circuit 300 having such a configuration.

As described above, in the semiconductor devices 10A, 10B, 10C, 10D, and the like, the channel layer 12 is provided on the uneven layer 20 having an adjusted uneven shape, and the surface flatness of the channel layer 12 is improved. Thereby, the quantum confinement structure 30 with an enhanced electron confinement effect is implemented. The high-performance PFC circuit 300 using the semiconductor device 10A, 10B, 10C, 10D, or the like, having such a quantum confinement structure 30, functioning as a HEMT having a high carrier mobility and a low leakage current, and having excellent characteristics is implemented.

Furthermore, the above-described semiconductor device 10E or the like functioning as an SBD may be used for the diode 320 and the diode bridge 360 of the PFC circuit 300. As described above, in the semiconductor device 10E and the like, the channel layer 12 is provided on the uneven layer 20 having an adjusted uneven shape, and the surface flatness of the channel layer 12 is improved. Thereby, the quantum confinement structure 30 with an enhanced electron confinement effect is implemented. The high-performance PFC circuit 300 using the semiconductor device 10E or the like, having such a quantum confinement structure 30, functioning as an SBD having a high carrier mobility and a low leakage current, and having excellent characteristics is implemented.

### Eighth Embodiment

Here, an application of a semiconductor device having a configuration as described above to a power supply device will be described as an eighth embodiment.

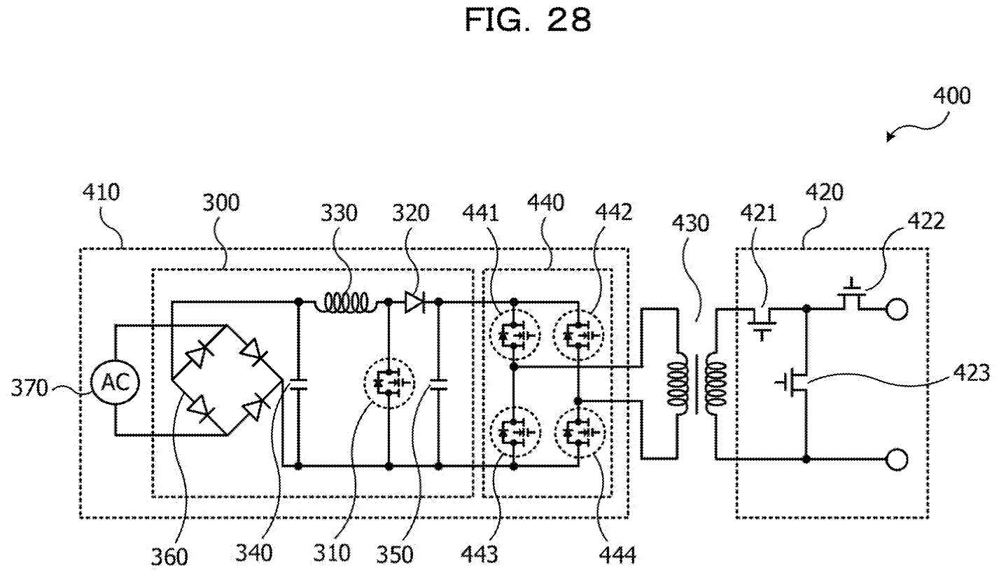

FIG. 28 is a diagram illustrating an example of a power supply device according to the eighth embodiment. FIG. 28 illustrates an equivalent circuit diagram of an example of the power supply device.

A power supply device 400 illustrated in FIG. 28 includes a high-voltage primary-side circuit 410, a low-voltage secondary-side circuit 420, and a transformer 430 provided between the primary-side circuit 410 and the secondary-side circuit 420.

The primary-side circuit 410 includes a PFC circuit 300 as described in the above seventh embodiment, and an inverter circuit such as a full-bridge inverter circuit 440 connected between both terminals of a capacitor 350 of the PFC circuit 300. The full-bridge inverter circuit 440 includes a plurality of (here, four as an example) switch elements 441, 442, 443, and 444.

The secondary-side circuit 420 includes a plurality of (here, three as an example) switch elements 421, 422, and 423.

For example, the above-described semiconductor device 10A, 10B, 10C, 10D, or the like functioning as a HEMT is used for the switch element 310 of the PFC circuit 300 and the switch elements 441 to 444 of the full-bridge inverter circuit 440 of the primary-side circuit 410 of the power supply device 400 having such a configuration. For example, a normal metal insulator semiconductor (MIS) field effect transistor using silicon is used for the switch elements 421 to 423 of the secondary-side circuit 420 of the power supply device 400.

As described above, in the semiconductor devices 10A, 10B, 10C, 10D, and the like, the channel layer 12 is provided on the uneven layer 20 having an adjusted uneven shape, and the surface flatness of the channel layer 12 is improved. Thereby, the quantum confinement structure 30 with an enhanced electron confinement effect is implemented. The high-performance power supply device 400 using the semiconductor device 10A, 10B, 10C, 10D, or the like, having such a quantum confinement structure 30, functioning as a HEMT having a high carrier mobility and a low leakage current, and having excellent characteristics is implemented.

Furthermore, the semiconductor device 10E or the like functioning as an SBD may be used for the diode 320 and the diode bridge 360 of the PFC circuit 300 included in the primary-side circuit 410, as described in the seventh embodiment above. The high-performance PFC circuit 300 is implemented using the semiconductor device 10E or the like having excellent characteristics, and the high-performance power supply device 400 is implemented using such a PFC circuit 300.

### Ninth Embodiment

Here, an application of a semiconductor device having a configuration as described above to an amplifier will be described as a ninth embodiment.

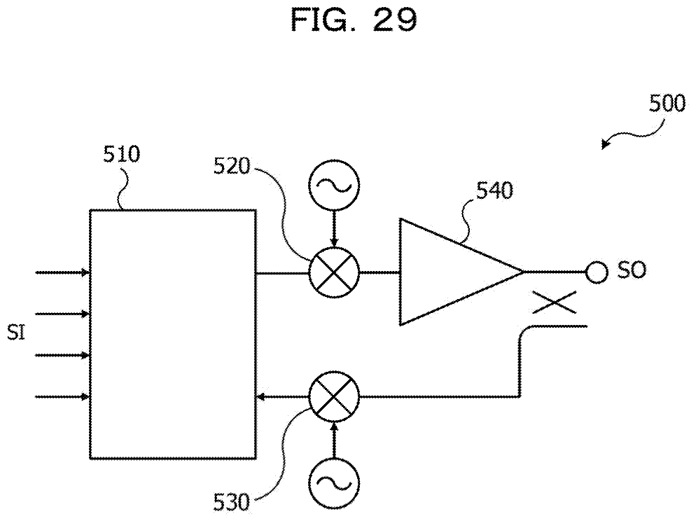

FIG. 29 is a diagram illustrating an example of an amplifier according to the ninth embodiment. FIG. 29 illustrates an equivalent circuit diagram of an example of the amplifier.

An amplifier 500 illustrated In FIG. 29 includes a digital predistortion circuit 510, a mixer 520, a mixer 530, and a power amplifier 540.

The digital predistortion circuit 510 compensates for nonlinear distortion of an input signal. The mixer 520 mixes an input signal SI compensated for its nonlinear distortion with an AC signal. The power amplifier 540 amplifies a signal obtained by mixing the input signal SI with the AC signal. The amplifier 500 can, for example, mix an output signal SO with the AC signal using the mixer 530 by switching a switch and can send out the mixed signal to the digital predistortion circuit 510. The amplifier 500 can be used as a high-frequency amplifier or a high-output amplifier.

The above-described semiconductor device 10A, 10B, 10C, 10D, or the like which functions as a HEMT is used for the power amplifier 540 of the amplifier 500 having such a configuration.

As described above, in the semiconductor devices 10A, 10B, 10C, 10D, and the like, the channel layer 12 is provided on the uneven layer 20 having an adjusted uneven shape, and the surface flatness of the channel layer 12 is improved. Thereby, the quantum confinement structure 30 with an enhanced electron confinement effect is implemented. The high-performance amplifier 500 using the semiconductor device 10A, 10B, 10C, 10D, or the like, having such a quantum confinement structure 30, functioning as a HEMT having a high carrier mobility and a low leakage current, and having excellent characteristics is implemented.

Furthermore, an SBD such as the semiconductor device 10E or the like may be used for a diode in a case where the diode is used for the amplifier 500. As described above, in the semiconductor device 10E and the like, the channel layer 12 is provided on the uneven layer 20 having an adjusted uneven shape, and the surface flatness of the channel layer 12 is improved. Thereby, the quantum confinement structure 30 with an enhanced electron confinement effect is implemented. The high-performance amplifier 500 using the semiconductor device 10E or the like, having such a quantum confinement structure 30, functioning as an SBD having a high carrier mobility and a low leakage current, and having excellent characteristics is implemented.

Various electronic devices to which the above-described semiconductor devices 10A, 10B, 10C, 10D, 10E or the like is applied (the semiconductor package 200, the PFC circuit 300, the power supply device 400, the amplifier 500, and the like described In the sixth to ninth embodiments) can be mounted on various types of electronic equipment. For example, such electronic devices can be mounted on various types of electronic equipment such as a computer (a personal computer, a supercomputer, a server, or the like), a smartphone, a portable telephone, a tablet terminal, a sensor, a camera, an audio apparatus, a measuring device, an inspection device, and a manufacturing device.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A semiconductor device comprising:
a substrate that contains a first nitride semiconductor;
an uneven layer that is provided on the substrate, contains a second nitride semiconductor, and has unevenness in a surface;
a channel layer that is provided on the uneven layer and contains a third nitride semiconductor; and
a barrier layer that is provided on the channel layer and contains a fourth nitride semiconductor, wherein,
in the uneven layer, an area of a portion that falls within a range within a mode value±1 nm of a position of the surface in a height direction falls within a range of 46% to 75% with respect to an area of the entire surface.

2. The semiconductor device according to claim 1, wherein, in the uneven layer, an area of a portion located at the mode value+1 nm or more of the position of the surface in a height direction is less than 3% with respect to the area of the entire surface.

3. The semiconductor device according to claim 1, wherein, in the uneven layer, an area of a portion located at the mode value−3 nm or less of positions of the surface in a height direction is less than 30% with respect to the entire area of the surface.

4. The semiconductor device according to claim 1, wherein both the area of the portion and the entire area are areas in a unit region of 1 μm².

5. The semiconductor device according to claim 1, wherein
the second nitride semiconductor is AlN,
the third nitride semiconductor is BₓAl_{y}Ga_{1-x-y}N (0≤x<1, 0≤y<1, and 0≤x+y<1), and
the fourth nitride semiconductor is Al_{z}Ga_{1-z}N (0<z≤1).

6. The semiconductor device according to claim 5, wherein the first nitride semiconductor is AlN.

7. A method for manufacturing a semiconductor device comprising:
forming, on a substrate that contains a first nitride semiconductor, an uneven layer that contains a second nitride semiconductor and has unevenness in a surface;
forming a channel layer that contains a third nitride semiconductor on the uneven layer; and
forming a barrier layer that contains a fourth nitride semiconductor on the channel layer, wherein,
the forming an uneven layer includes forming the uneven layer in which an area of a portion that falls within a range within a mode value±1 nm of a position of the surface in a height direction falls within a range of 46% to 75% with respect to an area of the entire surface.

8. The method for manufacturing a semiconductor device according to claim 7, wherein the forming an uneven layer includes forming the second nitride semiconductor that has the unevenness by epitaxial growth with a V/III ratio that falls within a range of 22000 to 67000, the V/III ratio being a molar ratio of a source gas of N that is a group V element of the second nitride semiconductor and a source gas of a group III element.

9. An electronic device comprising:
a semiconductor device including
a substrate that contains a first nitride semiconductor,
an uneven layer that is provided on the substrate, contains a second nitride semiconductor, and has unevenness in a surface,
a channel layer that is provided on the uneven layer and contains a third nitride semiconductor, and
a barrier layer that is provided on the channel layer and contains a fourth nitride semiconductor, and
in the uneven layer, an area of a portion that falls within a range within a mode value±1 nm of a position of the surface in a height direction that falls within a range of 46% to 75% with respect to an area of the entire surface.
